(19) United States
(12) Patent Application Publication
(10) Pub. No.: US 2015/0255287 A1
(43) Pub. Date: Sep. 10, 2015

(54) MANUFACTURING METHOD OF SEMICONDUCTOR DEVICE

(71) Applicant: Renesas Electronics Corporation, Kanagawa (JP)

(72) Inventors: Kenichi SHOJI, Kanagawa (JP); Yoshinori KONDA, Kanagawa (JP); Yuki OTA, Kanagawa (JP); Keiji OKAMOTO, Kanagawa (JP); Yuichi SUZUKI, Kanagawa (JP); Shutaro TSUCHIMOCHI, Kanagawa (JP); Kengo MATSUMOTO, Kanagawa (JP); Kazuyuki OZEKI, Kanagawa (JP)

(21) Appl. No.: 14/640,668

(22) Filed: Mar. 6, 2015

(30) Foreign Application Priority Data
Mar. 7, 2014 (JP) 2014-045202

(51) Int. Cl. H01L 21/266; H01L 21/3213; H01L 21/8234; H01L 21/311

(52) U.S. Cl. CPC H01L 21/266; H01L 21/31116; H01L 21/31144; H01L 21/32135; H01L 21/32139; H01L 21/8234

(57) ABSTRACT

To improve characteristics of a semiconductor device.

An element isolation region is etched by using a photoresist film as a mask, and thereby a p-type well that is a layer under the element isolation region is exposed. Thereafter, deposit over a surface of the photoresist film is etched. Then, a source region is formed by implanting impurity ions into the exposed p-type well by using the photoresist film as a mask, and thereafter, the photoresist film is removed. Thereby, it is possible to prevent a hardened layer from being formed due to injection of impurity ions into the deposit over the surface of the photoresist film. As a result, it is possible to suppress a popping phenomenon when the photoresist film is removed, so that it is possible to prevent a pattern of a gate and the like from being broken.

### CROSS-REFERENCE TO RELATED APPLICATION

The disclosure of Japanese Patent Application No. 2014-045202 filed on Mar. 7, 2014 including the specification, drawings and abstract is incorporated herein by reference in its entirety.

### BACKGROUND

The present invention relates to a manufacturing method of a semiconductor device. In particular, the present invention is suitably applied to a manufacturing method of a semiconductor device which uses an etching technique and an ion implantation technique.

In a manufacturing process of a semiconductor device, the etching technique and the ion implantation technique are used. For example, Japanese Patent Laid-Open No. 1999-97421 (Patent Literature 1) discloses a technique in which after a process of implanting ions of an element into a foundation layer and a resist, an upper layer including the elements, which is formed in a surface of the resist, is ashed in a radical atmosphere including oxygen radicals.

Further, Japanese Patent Laid-Open No. 2008-235660 (Patent Literature 2) discloses a technique in which after a part of a low dielectric constant film is plasma-etched by using a resist film as a mask, when the resist film is removed, preprocessing ashing is performed before performing ashing. In the preprocessing ashing, a substrate to be processed is maintained in a temperature range from 80° C. to 200° C. and the ashing is performed for a predetermined time.

Further, Japanese Patent Laid-Open No. 1999-162936 (Patent Literature 3) discloses a technique in which in a method of removing a resist, light ashing in a first ashing chamber, main ashing in a second ashing chamber, and after-light-ashing in the first chamber are performed, so that high resist peeling performance and high processing capability are achieved by the three times of ashing.

### SUMMARY

A manufacturing process of various semiconductor devices includes an etching process and an ion implantation process. In the manufacturing process, the etching process and the ion implantation process may be continuously performed.

In a manufacturing process of a semiconductor device including such processes, it is desirable that accurate etching and ion implantation are performed while simplifying the manufacturing process.

The other purposes and new features will become clear from the description of the present specification and the accompanying drawings.

The following explains briefly the outline of a typical embodiment among the embodiments disclosed in the present application.

In a manufacturing method of a semiconductor device described in an embodiment disclosed in the present application, a lower layer of a first film is exposed by etching the first film by using a photoresist film as a mask and thereafter a surface of the photoresist film is etched. Then, impurity ions are implanted into the lower layer of the first film by using the photoresist film as a mask and thereafter the photoresist film is removed.

According to a manufacturing method of a semiconductor device described in a typical embodiment disclosed in the present application, it is possible to manufacture a semiconductor device having excellent characteristics.

### BRIEF DESCRIPTION OF THE DRAWINGS

FIGS. 1A to 1D are cross-sectional views schematically showing a manufacturing process of a semiconductor device of a First Embodiment;

FIGS. 2A1 to 2C1 and 2A2 to 2C2 are cross-sectional views schematically showing a manufacturing process of a semiconductor device of a comparative example of the First Embodiment;

FIG. 3 is a cross-sectional view showing the manufacturing process of the semiconductor device of the First Embodiment;

FIG. 4 is a cross-sectional view showing the manufacturing process of the semiconductor device of the First Embodiment;

FIG. 5 is a cross-sectional view showing the manufacturing process of the semiconductor device of the First Embodiment, and is the cross-sectional view following FIG. 3;

FIG. 6 is a cross-sectional view showing the manufacturing process of the semiconductor device of the First Embodiment, and is the cross-sectional view following FIG. 4;

FIG. 7 is a cross-sectional view showing the manufacturing process of the semiconductor device of the First Embodiment, and is the cross-sectional view following FIG. 5;

FIG. 8 is a cross-sectional view showing the manufacturing process of the semiconductor device of the First Embodiment, and is the cross-sectional view following FIG. 6;

FIG. 9 is a cross-sectional view showing the manufacturing process of the semiconductor device of the First Embodiment, and is the cross-sectional view following FIG. 7;

FIG. 10 is a cross-sectional view showing the manufacturing process of the semiconductor device of the First Embodiment, and is the cross-sectional view following FIG. 8;

FIG. 11 is a cross-sectional view showing the manufacturing process of the semiconductor device of the First Embodiment, and is the cross-sectional view following FIG. 9;

FIG. 12 is a cross-sectional view showing the manufacturing process of the semiconductor device of the First Embodiment, and is the cross-sectional view following FIG. 10;

FIG. 13 is a plan view showing the manufacturing process of the semiconductor device of the First Embodiment;

FIG. 14 is a cross-sectional view showing the manufacturing process of the semiconductor device of the First Embodiment, and is the cross-sectional view following FIG. 11;

FIG. 15 is a cross-sectional view showing the manufacturing process of the semiconductor device of the First Embodiment, and is the cross-sectional view following FIG. 12;

FIG. 16 is a cross-sectional view showing the manufacturing process of the semiconductor device of the First Embodiment, and is the cross-sectional view following FIG. 14;

FIG. 17 is a cross-sectional view showing the manufacturing process of the semiconductor device of the First Embodiment, and is the cross-sectional view following FIG. 15;

FIG. 18 is a plan view showing the manufacturing process of the semiconductor device of the First Embodiment;

FIG. 19 is a cross-sectional view showing the manufacturing process of the semiconductor device of the First Embodiment, and is the cross-sectional view following FIG. 16;

FIG. 20 is a cross-sectional view showing the manufacturing process of the semiconductor device of the First Embodiment, and is the cross-sectional view following FIG. 17;

FIG. 21 is a cross-sectional view showing the manufacturing process of the semiconductor device of the First Embodiment, and is the cross-sectional view following FIG. 19;

FIG. 22 is a cross-sectional view showing the manufacturing process of the semiconductor device of the First Embodiment, and is the cross-sectional view following FIG. 20;

FIG. 23 is a cross-sectional view showing the manufacturing process of the semiconductor device of the First Embodiment, and is the cross-sectional view following FIG. 21;

FIG. 24 is a cross-sectional view showing the manufacturing process of the semiconductor device of the First Embodiment, and is the cross-sectional view following FIG. 22;

FIG. 25 is a cross-sectional view showing the manufacturing process of the semiconductor device of the First Embodiment, and is the cross-sectional view following FIG. 23;

FIG. 26 is a cross-sectional view showing the manufacturing process of the semiconductor device of the First Embodiment, and is the cross-sectional view following FIG. 24;

FIG. 27 is a cross-sectional view showing the manufacturing process of the semiconductor device of the First Embodiment, and is the cross-sectional view following FIG. 25;

FIG. 28 is a cross-sectional view showing the manufacturing process of the semiconductor device of the First Embodiment, and is the cross-sectional view following FIG. 26;

FIG. 29 is a plan view showing the manufacturing process of the semiconductor device of the First Embodiment;

FIG. 30 is a cross-sectional view showing the manufacturing process of the semiconductor device of the First Embodiment, and is the cross-sectional view following FIG. 27;

FIG. 31 is a cross-sectional view showing the manufacturing process of the semiconductor device of the First Embodiment, and is the cross-sectional view following FIG. 28;

FIG. 32 is a cross-sectional view showing the manufacturing process of the semiconductor device of the First Embodiment;

FIG. 33 is a plan view showing the manufacturing process of the semiconductor device of the First Embodiment;

FIG. 34 is a cross-sectional view showing the manufacturing process of the semiconductor device of the First Embodiment, and is the cross-sectional view following FIG. 30;

FIG. 35 is a cross-sectional view showing the manufacturing process of the semiconductor device of the First Embodiment, and is the cross-sectional view following FIG. 31;

FIG. 36 is a cross-sectional view showing the manufacturing process of the semiconductor device of the First Embodiment, and is the cross-sectional view following FIG. 34;

FIG. 37 is a cross-sectional view showing the manufacturing process of the semiconductor device of the First Embodiment, and is the cross-sectional view following FIG. 35;

FIG. 38 is a cross-sectional view showing the manufacturing process of the semiconductor device of the First Embodiment, and is the cross-sectional view following FIG. 36;

FIG. 39 is a cross-sectional view showing the manufacturing process of the semiconductor device of the First Embodiment, and is the cross-sectional view following FIG. 37;

FIG. 40 is a cross-sectional view showing the manufacturing process of the semiconductor device of the First Embodiment, and is the cross-sectional view following FIG. 38;

FIG. 41 is a cross-sectional view showing the manufacturing process of the semiconductor device of the First Embodiment, and is the cross-sectional view following FIG. 39;

FIG. 42 is a cross-sectional view showing the manufacturing process of the semiconductor device of the First Embodiment, and is the cross-sectional view following FIG. 40;

FIG. 43 is a cross-sectional view showing the manufacturing process of the semiconductor device of the First Embodiment, and is the cross-sectional view following FIG. 41;

FIG. 44 is a cross-sectional view showing the manufacturing process of the semiconductor device of the First Embodiment, and is the cross-sectional view following FIG. 42;

FIG. 45 is a cross-sectional view showing the manufacturing process of the semiconductor device of the First Embodiment, and is the cross-sectional view following FIG. 43;

FIG. 46 is a cross-sectional view showing the manufacturing process of the semiconductor device of the First Embodiment, and is the cross-sectional view following FIG. 44;

FIG. 47 is a cross-sectional view showing the manufacturing process of the semiconductor device of the First Embodiment, and is the cross-sectional view following FIG. 45;

FIG. 48 is a plan view showing the manufacturing process of the semiconductor device of the First Embodiment;

FIG. 49 is a cross-sectional view showing a characteristic manufacturing process of the semiconductor device of the First Embodiment;

FIG. 50 is a cross-sectional view showing the characteristic manufacturing process of the semiconductor device of the First Embodiment;

FIG. 51 is a cross-sectional view showing the characteristic manufacturing process of the semiconductor device of the First Embodiment;

FIG. 52 is a cross-sectional view showing the characteristic manufacturing process of the semiconductor device of the First Embodiment;

FIG. 53 is a cross-sectional view showing a manufacturing process of a semiconductor device of a Second Embodiment;

FIG. 54 is a cross-sectional view showing the manufacturing process of the semiconductor device of the Second Embodiment, and is the cross-sectional view following FIG. 53;

FIG. 55 is a cross-sectional view showing the manufacturing process of the semiconductor device of the Second Embodiment, and is the cross-sectional view following FIG. 54;

FIG. 56 is a cross-sectional view showing the manufacturing process of the semiconductor device of the Second Embodiment, and is the cross-sectional view following FIG. 55;

FIG. 57 is a cross-sectional view showing a manufacturing process of a semiconductor device of a comparative example;

FIGS. 58(a) and 58(b) are cross-sectional views showing the manufacturing process of the semiconductor device of the comparative example;

FIG. 59 is a cross-sectional view showing a manufacturing process of a semiconductor device of a Fourth Embodiment;

FIG. 60 is a cross-sectional view showing the manufacturing process of the semiconductor device of the Fourth Embodiment, and is the cross-sectional view following FIG. 59;

FIG. 61 is a cross-sectional view showing the manufacturing process of the semiconductor device of the Fourth Embodiment, and is the cross-sectional view following FIG. 60;

FIG. 62 is a cross-sectional view showing the manufacturing process of the semiconductor device of the Fourth Embodiment, and is the cross-sectional view following FIG. 61;

FIG. 63 is a cross-sectional view showing the manufacturing process of the semiconductor device of the Fourth Embodiment, and is the cross-sectional view following FIG. 62;

FIG. 64 is a cross-sectional view showing the manufacturing process of the semiconductor device of the Fourth Embodiment, and is the cross-sectional view following FIG. 63;

FIG. 65 is a cross-sectional view showing the manufacturing process of the semiconductor device of the Fourth Embodiment, and is the cross-sectional view following FIG. 64;

FIG. 66 is a cross-sectional view showing the manufacturing process of the semiconductor device of the Fourth Embodiment, and is the cross-sectional view following FIG. 65;

FIG. 67 is a cross-sectional view showing the manufacturing process of the semiconductor device of the Fourth Embodiment, and is the cross-sectional view following FIG. 66; and

FIG. 68 is a cross-sectional view showing the manufacturing process of the semiconductor device of the Fourth Embodiment, and is the cross-sectional view following FIG. 67.

### DETAILED DESCRIPTION

The following embodiments will be explained, divided into plural sections or embodiments, if necessary for convenience. Except for the case where it shows clearly in particular, they are not mutually unrelated and one has relationships such as a modification, an application, detailed explanation, and supplementary explanation of some or entire of another. In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, an element (including an element step etc.) is not necessarily indispensable, except for the case where it is clearly specified in particular and where it is considered to be clearly indispensable from a theoretical point of view, etc. Similarly, in the following embodiments, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the number, etc. described above (including the number, a numeric value, an amount, a range, etc.).

Hereinafter, the embodiments will be described in detail with reference to the drawings. In all the drawings for explaining the embodiments, the same symbol or a related symbol is attached to a member having the same function and the repeated explanation thereof is omitted. When there is a plurality of similar members (portions), an individual or a specific portion may be represented by adding a sign to a generic symbol. In the embodiments described below, explanation of the same or a similar portion is not repeated as a principle, except when the explanation is particularly required.

In the drawings used in the embodiments, in order to make a drawing intelligible, hatching may be omitted even if it is a cross-sectional view. Further, in order to make a drawing intelligible, hatching may be attached even if it is a plan view.

In a cross-sectional view and a plan view, the size of each portion does not correspond to an actual device and a specific portion may be shown in a relatively large size in order to make a drawing intelligible. Even when a cross-sectional view and a plan view correspond to each other, a specific portion may be shown in a relatively large size in order to make a drawing intelligible.

### First Embodiment

Hereinafter, a manufacturing process of a semiconductor device of the present embodiment will be described with reference to the drawings.

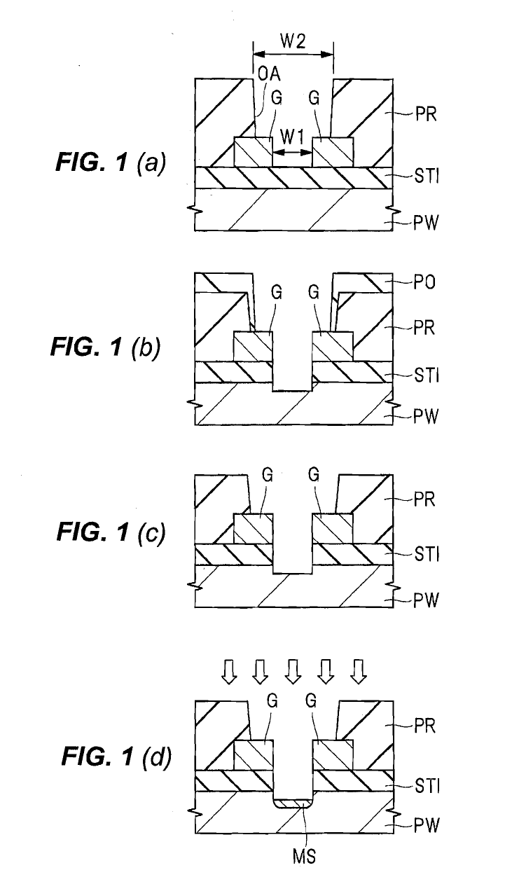

FIGS. 1A to 1D are cross-sectional views schematically showing the manufacturing process of the semiconductor device of the present embodiment.

FIGS. 1A to 1D show a process in which an element isolation region STI between two gates G located over the element isolation region STI is removed by etching and further a source region (source line) MS is formed by ion-implanting impurities between the gates G.

The gate G shown in FIG. 1A is formed over the element isolation region STI over a semiconductor substrate (p-type well PW). A photoresist film PR is formed over the gates G and the element isolation region STI and the photoresist film PR over a region in which the source region MS is formed is removed by a photolithography technique (exposure-development process). In this case, it is difficult to form an opening portion (contact hole) OA so that an end portion of the gate G and an end portion of the photoresist film PR coincide with each other. Therefore, an opening portion having a width (W2) greater than a distance (W1) between the gates G is formed. Thus, as shown in the drawings, the end portion of the photoresist film PR is located over the gate G.

Subsequently, as shown in FIG. 1B, the semiconductor substrate (p-type well PW) is exposed by dry etching the element isolation region STI between the gates G by using the photoresist film PR and the gates G as a mask. The dry etching is etching with depositional characteristics. Therefore, deposit (polymer) PO is formed over the upper surface and the side surface of the photoresist film PR. Generally, in etching, a lower layer is etched by using a photoresist film as a mask, and when the etching is performed, the thickness of the photoresist film is also reduced. Therefore, it is possible to protect the photoresist film by depositing the deposit (film-forming component and by-product) and improve etching accuracy by complementing the thickness reduction of the photoresist film. The etching as described above may be referred to as “etching with depositional characteristics” or “polymer etching”.

When a silicon oxide film is used as the element isolation region STI, as an etching gas, for example, fluorocarbon gas such as CF₄, CHF₃, CH₂F₂, C₄F₈, C₄F₆, and C₅F₈ can be used. When the gas as described above is used, while a film to be etched is being etched by CF radicals (CF*, CF₂*, and CF₃*), deposit PO including fluorocarbon-based polymer (CF-based polymer) is deposited over the upper surface and the side surface of the photoresist film as an etching by-product. The fluorocarbon is a compound having a carbon-fluorine bond. For example, it is possible to etch the element isolation region (silicon oxide film) by using mixed gas of CHF3 and CF4 as an etching gas.

Subsequently, as shown in FIG. 1C, the deposit PO over the upper surface and the side surface of the photoresist film PR is removed by slight ashing. To remove the deposit PO including fluorocarbon-based polymer (CF-based polymer), etching is performed by using oxygen as an etching gas. Ar (argon) may be introduced into an etching atmosphere. Ozone (O₃) may be used as the etching gas. It is not necessarily essential to add (introduce) Ar into the etching gas and apply a substrate bias (high-frequency potential). However, when elements whose mass number is greater than that of oxygen (O) are added into the etching gas and the substrate bias is applied, an etching speed is improved. In particular, the deposit (polymer) PO is harder than the photoresist film, so that when Ar is added and/or the substrate bias is applied, the etching speed can be increased and removability of the deposit (polymer) PO can be improved.

According to the small etching of the surface of the photoresist film (including the deposit) as described above (hereinafter referred to as “slight etching”), the slight etching has a small effect on the region that should be covered by the photoresist film PR, so that the photoresist film PR sufficiently plays a role of a mask film in a following ion implantation process. As an amount of the slight ashing (an amount of etching), it is preferable that the sight ashing is performed in a range from 50 to 300 nm. In particular, in the case shown in FIGS. 1C and 1D, the gate G also plays a role of the mask, so that the retreat of the photoresist film PR, which is smaller than the length of the gate, causes no problem.

Subsequently, as shown in FIG. 1D, the source region (n⁺-type semiconductor region) MS is formed by ion-implanting n-type impurities (for example, phosphorus (P)) into the exposed surface of the p-type well PW by using the photoresist film PR and the gates G as a mask.

Subsequently, the photoresist film PR is removed by ashing (an ash making process). Regarding an ashing condition, for example, ashing is performed by using oxygen or ozone as an ashing gas. In this ashing, even when Ar is not added and/or the substrate bias is not applied, ashing is performed faster than the ashing of the deposit (polymer) PO described above. Of course, Ar may be added to the gas and the bias potential may be applied to the substrate.

Normally, when performing ashing on the photoresist film by using O₂ gas, processing at high-temperature is preferred in order to vaporize CO₂, CO, and H₂O (water vapor), which are reactants between O₂ gas and a component of the photoresist film. On the other hand, in an etching apparatus, a high-frequency potential application mechanism for introducing ions into a substrate (wafer) is provided below a substrate mounting table and ionized gas is caused to hit the substrate and blows off (sputters) a film to be etched (here, the photoresist film). In this way, it is possible to perform ashing (remove polymer) by using the O₂ gas.

Further, it is possible to increase a polymer removal effect (an ashing rate) by ionizing atoms (elements) with a large mass such as Ar to apply a sputtering effect to the wafer. It is possible to adjust a gas flow rate and ion energy of the Ar+O₂ gas by using this principle, so that it is possible to optimally adjust a removal amount of the polymer.

In the actual adjustment, when the O₂ gas flow rate is increased, a polymer removal effect (ashing rate) can be increased. Further, when the ion energy is increased, the polymer removal effect (ashing rate) can also be increased.

However, when the ion energy is increased, a physical sputtering effect is applied to the portion other than the photoresist film (portion that is etched) by injection of the O₂ gas and the like, so that the ion energy is desired to be lower as much as possible.

On the other hand, the removal of the polymer can be performed by a general ashing apparatus. However, when an object is to remove the polymer and to ensure the film thickness of the photoresist film for ion implantation, the polymer cannot be removed in a well controlled manner unless the ashing is performed at low temperature and the ashing rate is very low. Further, after the etching, the wafer is once taken out of the apparatus, and then the wafer is processed by the ashing apparatus, so that the wafer is exposed to atmosphere and the polymer may change in quality. Therefore, the control of removal of the polymer may be difficult.

A general ashing apparatus often does not have a high-frequency potential application mechanism which is an ion introducing mechanism, so that from a viewpoint of controllability of removal of the polymer, a method is effective in which the polymer is continuously removed in the same etching chamber as that used in the process in FIG. 1B without taking out the wafer from the apparatus.

As described above, according to the present embodiment, after the etching process with depositional characteristics is performed, the slight ashing is performed, and then after the deposit PO deposited over the surface of the photoresist film PR is removed, the ion implantation of impurities is performed, so that it is possible to accurately perform the ashing of the photoresist film PR.

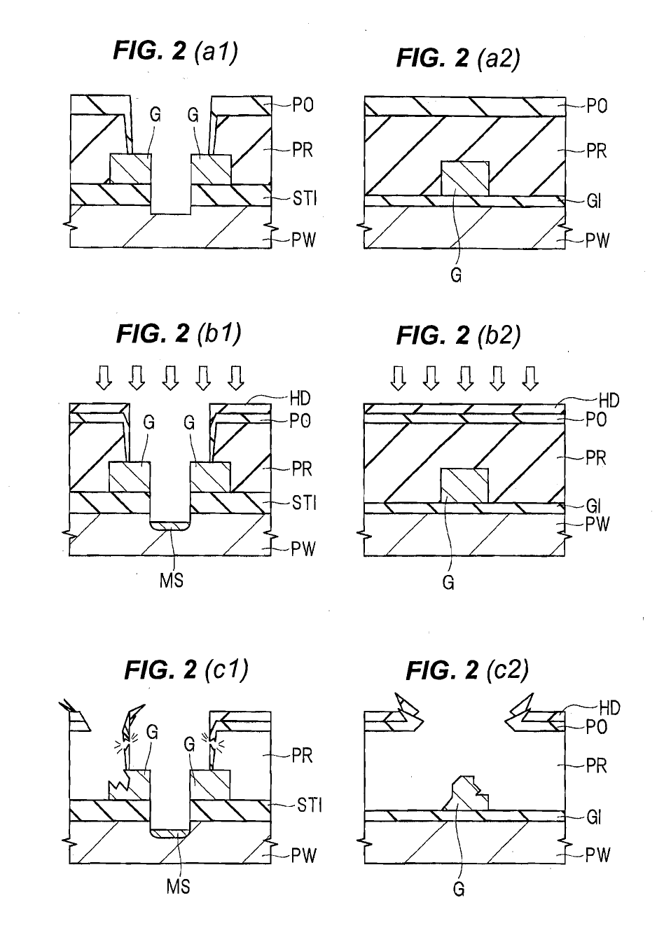

On the other hand, as shown in FIGS. 2A1 to 2C2, if the ion implantation is performed in a state in which the deposit PO is formed over the surface of the photoresist film PR, in a following ashing process, explosion (a popping phenomenon) of the photoresist film PR may occur. FIGS. 2A1 to 2C1 and 2A2 to 2C2 are cross-sectional views schematically showing a manufacturing process of a semiconductor device of a comparative example of the present embodiment.

FIGS. 2A1 to 2C1 show a region where a contact hole is formed by using the photoresist film PR. The region corresponds to a memory cell region MA described later. FIGS. 2A2 to 2C2 show a region covered by the photoresist film PR. For example, the region corresponds to a peripheral circuit region PA described later.

FIGS. 2A1 and 2A2 show a state in which the deposit PO is formed over the surface of the photoresist film PR. FIGS. 2B1 and 2B2 show formation of a hardened layer (an altered layer) HD by an ion implantation process. FIGS. 2C1 and 2C2 show the popping phenomenon by the ashing.

As shown in FIGS. 2A2 to 2C2, the popping phenomenon has a large negative effect on mainly the gate G. This is because the area covered by the photoresist film PR over the gate G is greater than the area covered by the photoresist film PR of the other region.

Specifically, as shown in FIG. 2B2, when the ion implantation is performed in a state in which the deposit PO is formed over the surface of the photoresist film PR, the impurity ions are also implanted into the deposit PO and a hardened layer (an altered layer) HD is formed.

Thereafter, as shown in FIG. 2C2, if the ashing is performed in a state in which the surface of the photoresist film PR is covered by the hard hardened layer (altered layer) HD, a vaporized gas (reactant gas) of the photoresist film is not discharged and the inner pressure in the photoresist film PR increases. Specifically, in the ashing, carbon (C) and hydrogen (H), which are main components of the photoresist film, react with oxygen (O₂) to form CO₂, CO, and H₂O (water vapor) and they are vaporized. For example, it is assumed that the processing temperature is 150° C. to 350° C. When the inner pressure reaches a limit, the photoresist film explodes (bursts).

Such a phenomenon is referred to as a “popping phenomenon”. When such a popping phenomenon occurs, the hardened layer HD and the deposit (polymer) PO spatter to unexpected positions and may become particles that are difficult to be removed. Further, a pattern of a lower layer such as the gate G is broken by the energy of the explosion. A chip region including such a defective element is removed in a following inspection process (an appearance inspection and a circuit operation test). However, the yield rate decreases. Even when the criteria of the circuit operation are satisfied, there is a risk that the characteristics of the circuit are relatively degraded. As described above, when the hardened layer HD spatters and/or the pattern of the gate G is broken, the characteristics of the semiconductor device may degrade and/or the yield rate of the semiconductor device may decrease. In particular, when implanting high-concentration impurity ions, the impurity ions are implanted into the deposit PO in high concentration, so that the hardened layer HD is easily formed and the hardened layer HD is further hardened and thickened. Therefore, the popping phenomenon easily occurs.

Also in the region shown in FIGS. 2A1 to 2C1, the popping phenomenon may occur in the same manner. Over the inner wall of the contact hole, most of the ion implantation is a vertical component, so that the thickness of the hardened layer HD is smaller than that of the hardened layer HD in the region shown in FIGS. 2A2 to 2C2. Therefore, the probability that the popping phenomenon occurs is smaller than that in the region shown in FIGS. 2A2 to 2C2. However, the popping phenomenon may occur in the same manner as described above. In this case, the worst case may be a case in which destruction occurs as shown by the left gate G in FIG. 2C1. FIG. 2C1 shows that the right gate G is not broken, but spattered deposits PO may become particles. From the above, as a result, there is concern that the yield rate may decrease.

On the other hand, in the present embodiment, after the etching process with depositional characteristics is performed, the slight ashing is performed, and then after the deposit deposited over the surface of the photoresist film PR is removed, the ion implantation of impurity ions is performed, so that it is possible to prevent a hardened layer from being formed due to injection of impurity ions into the deposit PO over the surface of the photoresist film PR. As a result, it is possible to suppress the explosion of the photoresist film (the popping phenomenon), so that it is possible to prevent the hardened layer from spattering and prevent the pattern of the gate and the like from being broken. Thereby, it is possible to improve the characteristics of the semiconductor device. Further, the yield rate can be improved. In particular, even when high-concentration impurity ions (for example, the concentration of n-type impurities is greater than or equal to 1×10E15/cm² and the concentration of p-type impurities is greater than or equal to 1×10E15/cm²) are implanted, the popping phenomenon of the photoresist film can be suppressed, 10E15 represents 10¹⁵.

In the slight ashing shown in FIG. 1C, it is preferable to completely remove the deposit PO. However, even when the deposit PO is partially removed or the thickness of the deposit PO is reduced, the suppression effect of the popping phenomenon is obtained. In other words, when the deposit PO is partially removed, it is possible to suppress the increase of the inner pressure in the photoresist film, and when the thickness of the deposit PO is small, the formed hardened layer HD is thin or the hardened layer HD is partially formed, so that the popping phenomenon can be suppressed.

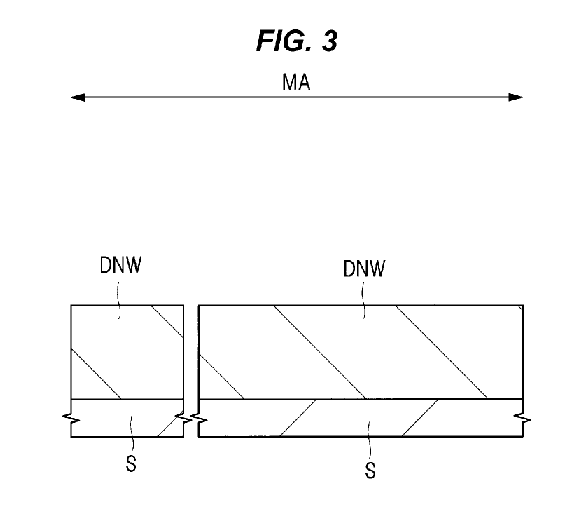

Hereinafter, a more specific semiconductor device will be illustrated and the present embodiment will be described in more detail according to the manufacturing process of the semiconductor device. FIGS. 3 to 48 are cross-sectional views or plan views showing the manufacturing process of the semiconductor device of the present embodiment.

### [Description of Structure]

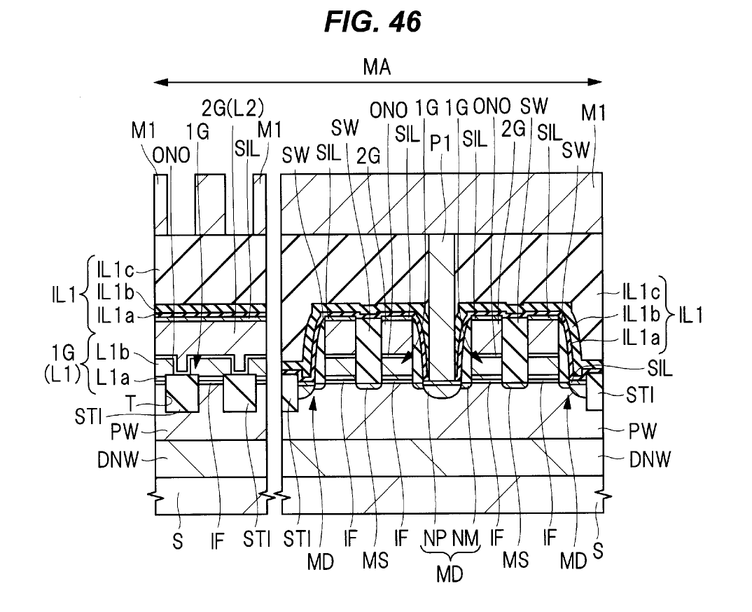

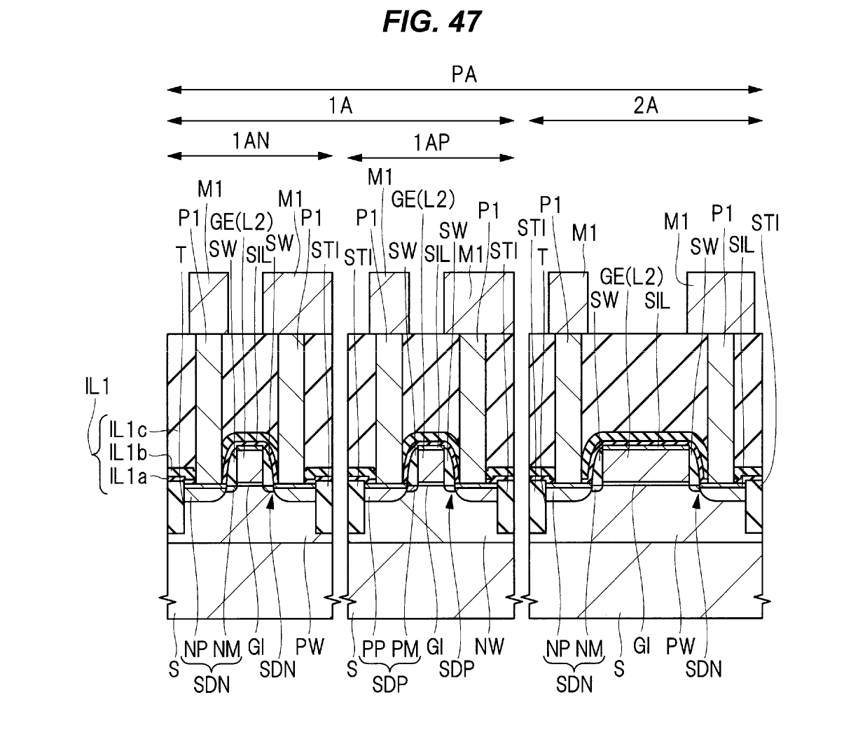

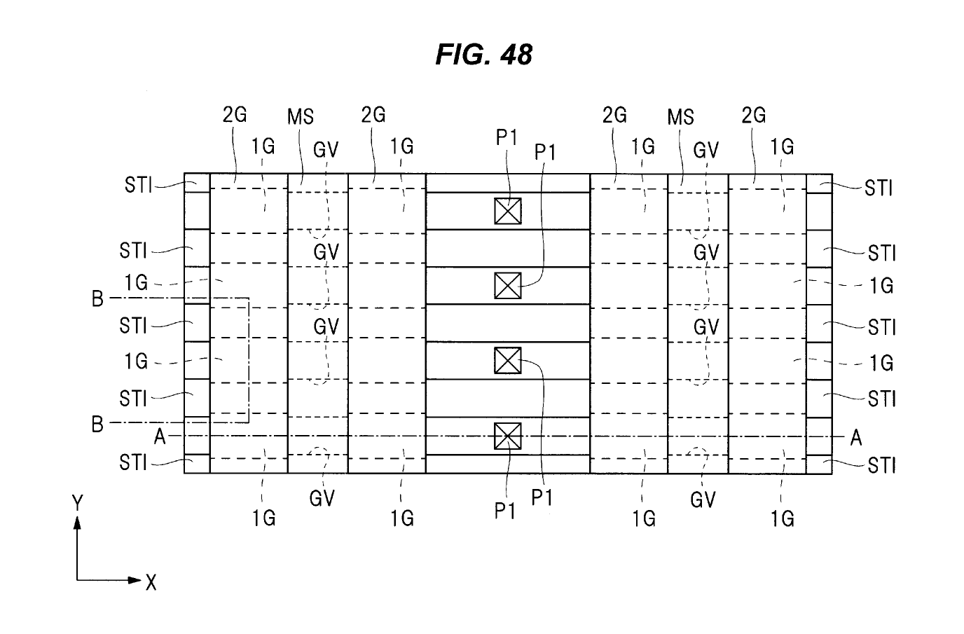

First, a configuration of the semiconductor device of the present embodiment will be described with reference to FIGS. 46 and 47, which are final process cross-sectional views, and FIG. 48, which is a final process plan view, from among the drawings shown in FIGS. 3 to 48.

As shown in FIGS. 46 to 48, the semiconductor device of the present embodiment includes a memory cell (memory transistor) formed in a memory cell region MA shown in FIG. 46 and a peripheral transistor formed in a peripheral circuit region PA shown in FIG. 47. The semiconductor device of the present embodiment is, for example, a microcomputer with built-in flash memory.

The peripheral circuit region PA includes a core region 1A and an I/O region (input/output region) 2A. In the core region 1A, a low breakdown voltage transistor is formed. In FIG. 47, as the low breakdown voltage transistor, an n-channel type transistor in a region 1AN and a p-channel type transistor in a region 1AP are illustrated. In the I/O region 2A, a high breakdown voltage transistor whose breakdown voltage is higher than that of the transistors formed in the core region 1A, and as the high breakdown voltage transistor, an n-channel type transistor is illustrated. The transistors formed in the peripheral circuit region PA are also called MISFET (Metal Insulator Semiconductor Field Effect Transistor).

### (Description of Structure of Memory Cell)

FIG. 46 is a cross-sectional view of the memory cell region MA. FIG. 48 is a plan view showing a memory array. For example, the right figure in FIG. 46 corresponds to an A-A portion in FIG. 48 and the left figure in FIG. 46 corresponds to a B-B portion in FIG. 48.

As shown in FIGS. 46 and 48, the memory cell includes a first gate 1G arranged over a semiconductor substrate S (p-type well PW) through an insulating film IF and a second gate 2G arranged over the first gate 1G through an insulating film ONO. The insulating film IF is formed of, for example, a silicon oxide film. The insulating film ONO is formed of, for example, a silicon oxide film, a silicon nitride film over silicon oxide film, and a silicon oxide film over the silicon nitride film. The silicon nitride film becomes a charge accumulation unit. Each of the first gate 1G and the second gate 2G is formed of a silicon film. A metal silicide film SIL is formed over the second gate 2G.

A source region MS is arranged in the semiconductor substrate S (p-type well PW) on one side of a laminated gate including the first gate 1G and the second gate 2G. A drain region MD is arranged in the semiconductor substrate S (p-type well PW) on the other side of the laminated gate. The memory cell including the laminated gate is repeatedly arranged. Each of the arranged memory cells commonly include the source region MS. In other words, the laminated gate is arranged over both sides of the source region MS and the drain regions MD are arranged outside the laminated gates. Other two laminated gates are arranged symmetrically with the two laminated gates on both sides of the source region MS with the drain region MD in between (see the right figure in FIG. 46).

The source region MS is formed of an n⁺-type semiconductor region. The n⁺-type semiconductor region is formed between the laminated gates. The drain region MD is formed of an n⁺-type semiconductor region NP and an n⁻-type semiconductor region NM. The n⁻-type semiconductor region NM is formed in a self-aligned manner with respect to the side wall of the laminated gate. The n⁺-type semiconductor region NP is formed in a self-aligned manner with respect to a side surface of a side wall insulating film SW formed over the side wall of the laminated gate. The junction depth of the n⁺-type semiconductor region NP is greater than that of the n⁻-type semiconductor region NM and the impurity concentration of the n⁺-type semiconductor region NP is higher than that of the n⁻-type semiconductor region NM. A drain electrode formed of such low concentration semiconductor region and high concentration semiconductor region is called an LDD (Lightly doped Drain) structure.

In the present specification, the source region MS and the drain region MD are defined based on during operation. Semiconductor regions where a high voltage is applied during a reading operation and to each of which a voltage is independently applied are collectively called the drain region MD and semiconductor regions where a low voltage is applied during a reading operation and each of which is caused to have a common potential are collectively called the source region MS.

The metal silicide film SIL is formed above the source region MS and the drain region MD.

Here, as shown in the left figure in FIG. 46, an exposed portion of the semiconductor substrate S (p-type well PW), which is an active region, and the element isolation region STI formed of an insulating film are alternately arranged, and the laminated gate is arranged over the active region.

An interlayer insulating film IL1 is arranged above the memory cell (the laminated gate), and further, a wiring M1 is arranged over the interlayer insulating film IL1. The wiring M1 is coupled to the drain region MD through a plug P1 in the interlayer insulating film IL1.

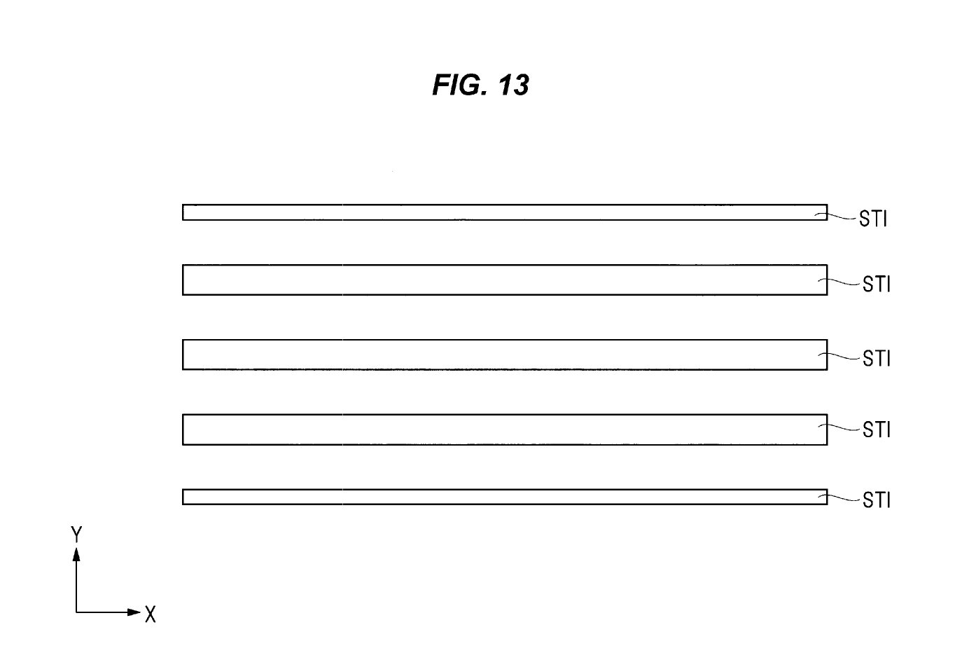

As shown in FIG. 48, the source region MS and the plug P1 over the drain region (MD) are alternately arranged in the X direction. The laminated gate (1G and 2G) is arranged between the source region MS and the plug P1 (the drain region MD). The second gate 2G included in the laminated gate is linearly arranged in the Y direction. The active region (an exposed region of the p-type well PW), in which the source region MS, the laminated gate (1G and 2G), and the drain region (MD) are arranged, is linearly arranged in the X direction, and the element isolation region STI is linearly arranged between the active regions (see FIG. 13). However, the source region MS is arranged in the Y direction, so that the element isolation region STI located in a region where the source region MS is formed is removed and n⁺-type semiconductor region is arranged.

### (Description of Structure of Peripheral Transistor)

As shown in FIG. 47, an n-channel type transistor in the region 1AN among low breakdown voltage transistors in the core region 1A includes a gate electrode GE arranged over the semiconductor substrate S (p-type well PW) through a gate insulating film GI and a source/drain region SDN provided in the p-type wells PW on both sides of the gate electrode GE. The gate electrode GE is formed of a silicon film, and for example, formed of the same material as that of the second gate 2G. A side wall insulating film SW formed of an insulating film is formed over the side wall portion of the gate electrode GE. The source/drain region SDN includes an n⁺-type semiconductor region NP and an n⁻-type semiconductor region NM. The n⁻-type semiconductor region NM is formed in a self-aligned manner with respect to the side wall of the gate electrode GE. The n⁺-type semiconductor region NP is formed in a self-aligned manner with respect to a side surface of a side wall insulating film SW. The junction depth of the n⁺-type semiconductor region NP is greater than that of the n⁻-type semiconductor region NM and the impurity concentration of the n⁺-type semiconductor region NP is higher than that of the n⁻-type semiconductor region NM. A metal silicide film SIL is formed over the gate electrode GE and the source/drain region SDN (n⁺-type semiconductor region NP).

The p-channel type transistor in the region 1AP among the low breakdown voltage transistors in the core region 1A includes a gate electrode GE arranged over the semiconductor substrate S (p-type well PW) through the gate insulating film GI and a source/drain region SDP provided in the n-type wells NW on both sides of the gate electrode GE. The gate electrode GE is formed of a silicon film, and for example, formed of the same material as that of the second gate 2G. A side wall insulating film SW formed of an insulating film is formed over the side wall portion of the gate electrode GE. The source/drain region SDP is formed of a p⁺-type semiconductor region PP and a p⁻-type semiconductor region PM. The p⁻-type semiconductor region PM is formed in a self-aligned manner with respect to the side wall of the gate electrode GE. The p⁺-type semiconductor region PP is formed in a self-aligned manner with respect to the side surface of the side wall insulating film SW. The junction depth of the p⁺-type semiconductor region PP is greater than that of the p⁻-type semiconductor region PM and the impurity concentration of the p⁺-type semiconductor region PP is higher than that of the p⁻-type semiconductor region PM. A metal silicide film SIL is formed over the gate electrode GE and the source/drain region SDP (p⁺-type semiconductor region PP).

An n-channel type transistor which is a high breakdown voltage transistor in the I/O region 2A includes a gate electrode GE arranged over the semiconductor substrate S (p-type well PW) through the gate insulating film GI and a source/drain region SDN provided in the p-type wells PW on both sides of the gate electrode GE. The gate electrode GE is formed of a silicon film, and for example, formed of the same material as that of the second gate 2G. A side wall insulating film SW formed of an insulating film is formed over the side wall portion of the gate electrode GE. The source/drain region SDN includes an n⁺-type semiconductor region NP and an n⁻-type semiconductor region NM. The n⁻-type semiconductor region NM is formed in a self-aligned manner with respect to the side wall of the gate electrode GE. The n⁺-type semiconductor region NP is formed in a self-aligned manner with respect to the side surface of the side wall insulating film SW. The junction depth of the n⁺-type semiconductor region NP is greater than that of the n⁻-type semiconductor region NM and the impurity concentration of the n⁺-type semiconductor region NP is higher than that of the n⁻-type semiconductor region NM. The transistor formed in the I/O region 2A has a breakdown voltage higher than that of the transistors formed in the core region 1A and has features that, for example, the thickness of the gate insulating film GI is greater than that of the transistors formed in the core region 1A and the gate length is greater than that of the transistors formed in the core region 1A. Although only the n-channel type transistor is illustrated here as a high breakdown voltage transistor, a p-channel type transistor may be formed.

An interlayer insulating film IL1 is arranged over the gate electrode GE of the peripheral transistor, and further, a wiring M1 is arranged over the interlayer insulating film IL1. The wiring M1 is coupled to the source/drain regions (SDN and SDP) and the like through a plug P1 in the interlayer insulating film IL1.

### [Description of Manufacturing Method]

Subsequently, a manufacturing method of the semiconductor device of the present embodiment will be described with reference to FIGS. 3 to 48.

Hereinafter, a process of forming a memory cell in the memory cell region MA and forming a peripheral transistor in the peripheral circuit region PA will be described with reference to the drawings.

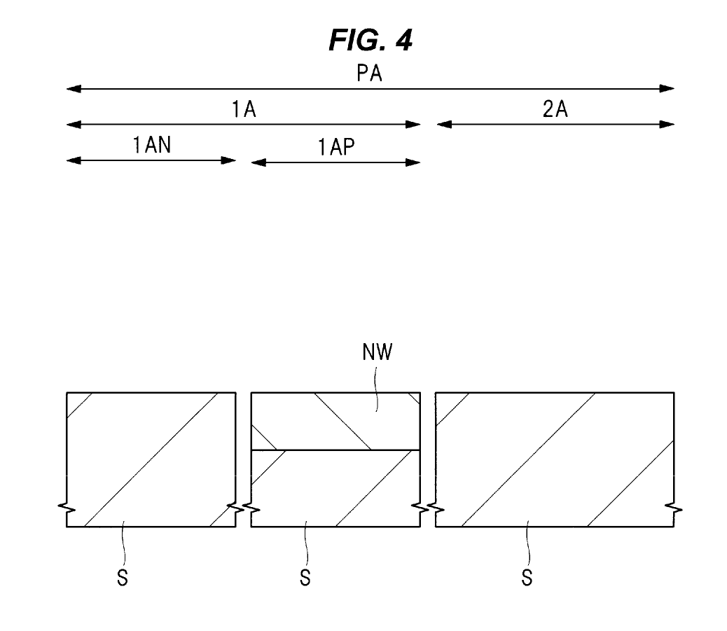

First, as shown in FIGS. 3 and 4, a semiconductor substrate formed of a silicon single crystal is prepared as the semiconductor substrate S. Then, n-type wells NW and DNW are formed in the semiconductor substrate S. For example, a deep n-type well DNW is formed by ion-implanting n-type impurities (for example, phosphorus (P)) into the memory cell region MA by using a silicon oxide film (not shown in the drawings) as a through film. Further, an n-type well NW is formed by ion-implanting n-type impurities (for example, phosphorus (P)) into the region 1AP. Regions into which ions are not implanted are covered by a photoresist film (not shown in the drawings).

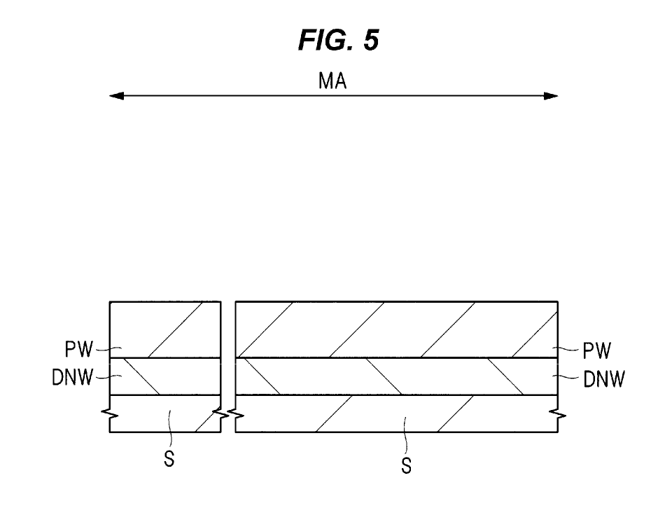

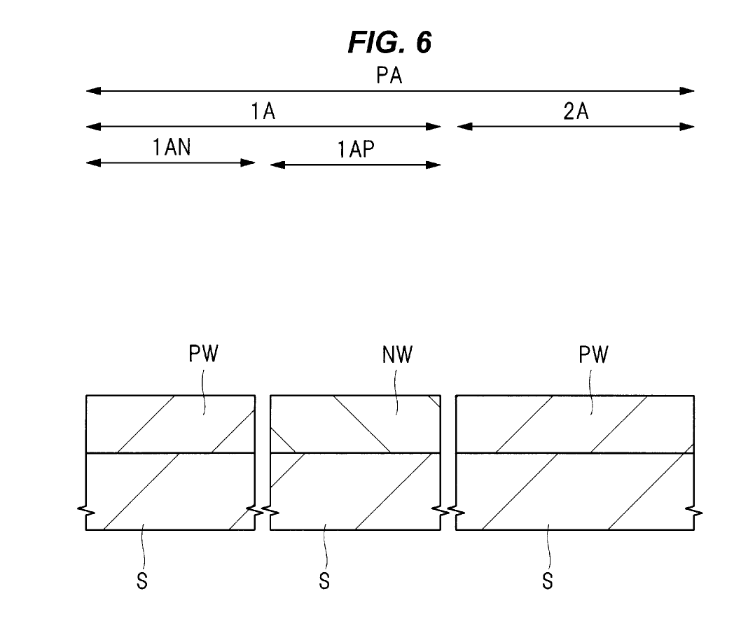

Subsequently, as shown in FIGS. 5 and 6, a p-type well PW is formed in the semiconductor substrate S. For example, a p-type well PW is formed by ion-implanting p-type impurities (for example, boron (B)) into the memory cell region MA (in the n-type well DNW) by using a silicon oxide film (not shown in the drawings) as a through film. Further, p-type wells PW are formed by ion-implanting p-type impurities (for example, boron (B)) into the region LAN and the I/O region 2A. Regions into which ions are not implanted are covered by a photoresist film (not shown in the drawings). Each well (NW, DNW, and PW) may be formed by individually implanting ions into each region or the wells may be formed at the same time if the conductivity types of the impurities included in the wells and the concentrations and the depths of the impurities included in the wells are substantially the same.

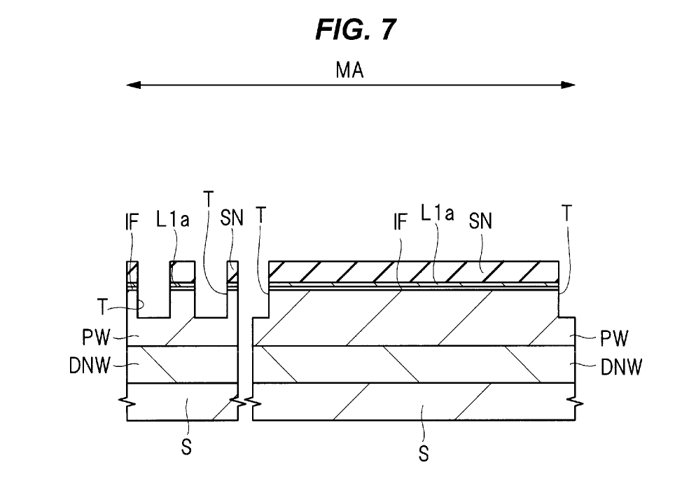

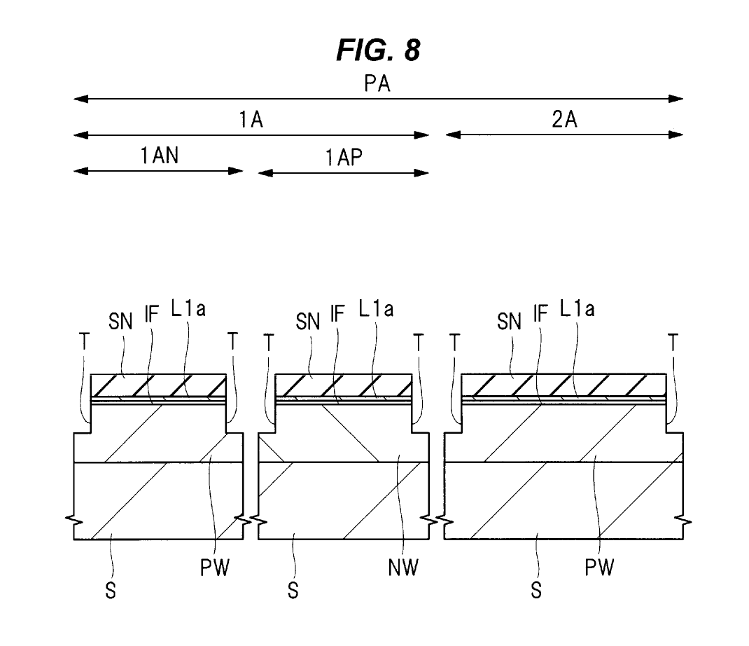

Next, as shown in FIGS. 7 and 8, insulating films (hard masks) such as an insulating film IF, a silicon film L1a, and a silicon nitride film SN are sequentially formed, and thereafter, a trench T is formed. First, as the insulating film IF, a silicon oxide film is formed over the semiconductor substrate S (well) by thermal oxidation. Subsequently, a polycrystalline or amorphous silicon film L1a is deposited over the insulating film IF by using a CVD (Chemical Vapor Deposition) method or the like while doping impurities or without doping impurities. When impurities are not doped, impurities can be doped by thermal diffusion of impurities from a silicon film L1b deposited over the silicon film L1a thereafter. The silicon film L1a becomes a part of the first gate 1G and the gate electrode GE. Other conductive material may be used as a material of the first gate 1G and the gate electrode GE. Subsequently, a silicon nitride film SN is deposited over the silicon film L1a by using the CVD method or the like.

Subsequently, a photoresist film (not shown in the drawings) is formed over the silicon nitride film SN, and the photoresist film in the element isolation region is removed by exposure and development processes.

Subsequently, the silicon nitride film SN is dry-etched by using the photoresist film as a mask. Subsequently, the photoresist film is removed by asking (an ash making process). Subsequently, a trench T for element isolation is formed by dry etching the silicon film L1a, the insulating film IF, and the semiconductor substrate S by using the silicon nitride film SN as a mask. At this time, the depth of the trench T is a first depth. The trench T is formed, for example, so as to surround each region (memory cell region MA, region 1AN, region 1AP, and I/O region 2A).

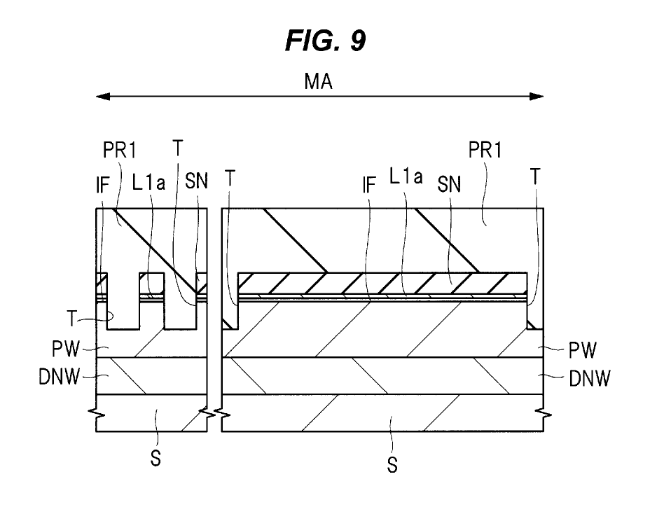

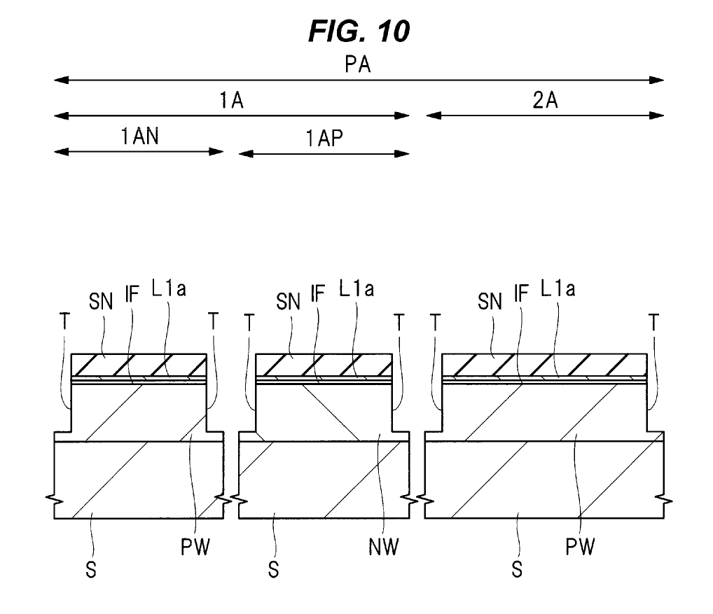

Subsequently, as shown in FIGS. 9 and 10, the depths of the trenches T in the peripheral circuit region PA are increased. This is performed in order to reduce crystal defects by maintaining the first depth in the memory cell region MA while improving the element isolation capability in the peripheral circuit region PA. First, a photoresist film PR1 is formed over the trench T and the silicon nitride film SN, and the photoresist film PR1 in the peripheral circuit region PA is removed by exposure and development processes. Subsequently, the bottom portion of the trench T is dry-etched by using the photoresist film PR1 and the silicon nitride film SN as a mask. Thereby, the depth of the trench T in the peripheral circuit region PA becomes a second depth greater than the first depth. Subsequently, the photoresist film PR1 is removed by ashing.

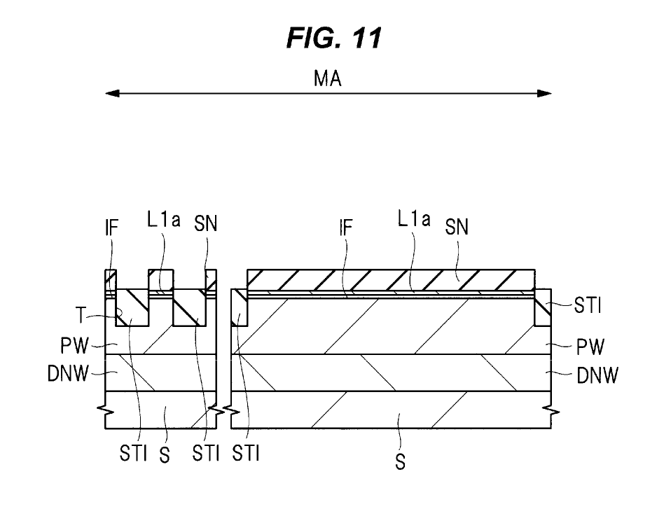

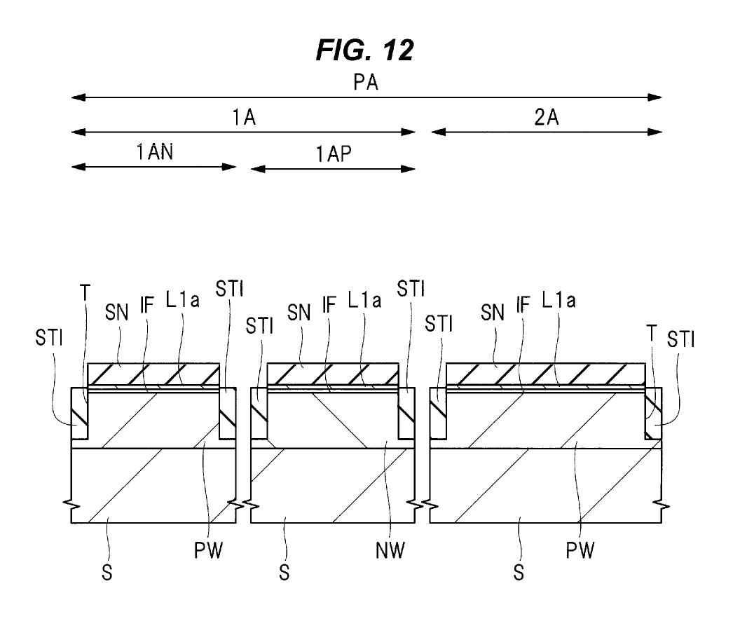

Subsequently, as shown in FIGS. 11 and 12, an element isolation region STI is formed. First, a silicon oxide film having a thickness to fill the inside of the trench T is deposited over the trench T and the silicon nitride film SN by using the CVD method or the like. Subsequently, the silicon oxide film other than the silicon oxide film in the trench T is removed by using a CMP (Chemical Mechanical Polishing) method or the like. Thereby, it is possible to form the element isolation region STI formed of an insulating film buried inside the trench T. This element isolation method is called a “Shallow Trench Isolation method”. As shown in FIG. 13, in the memory cell region MA, the element isolation region STI is formed into, for example, a rectangular shape (a linear shape) having the long side in the X direction. Further, a plurality of element isolation regions STI having a rectangular shape are provided at predetermined intervals in the Y direction. A region between the element isolation regions STI having a rectangular shape is the active region in which the memory cell is arranged. Subsequently, the silicon nitride film SN is removed by wet etching. For example, heat phosphoric acid is used as a solution of the wet etching.

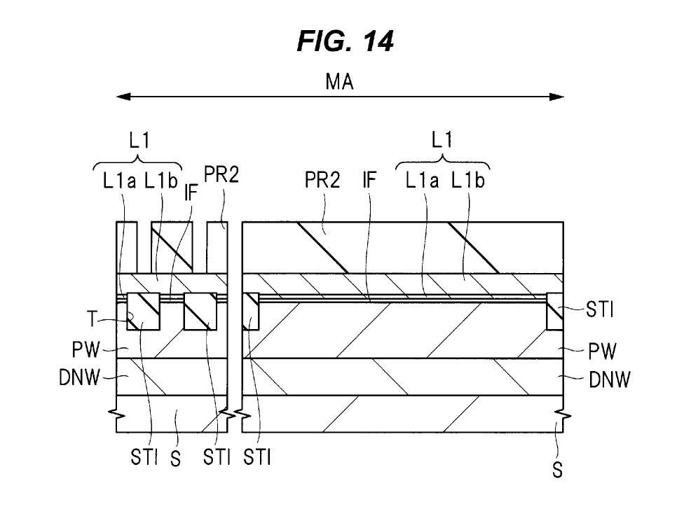

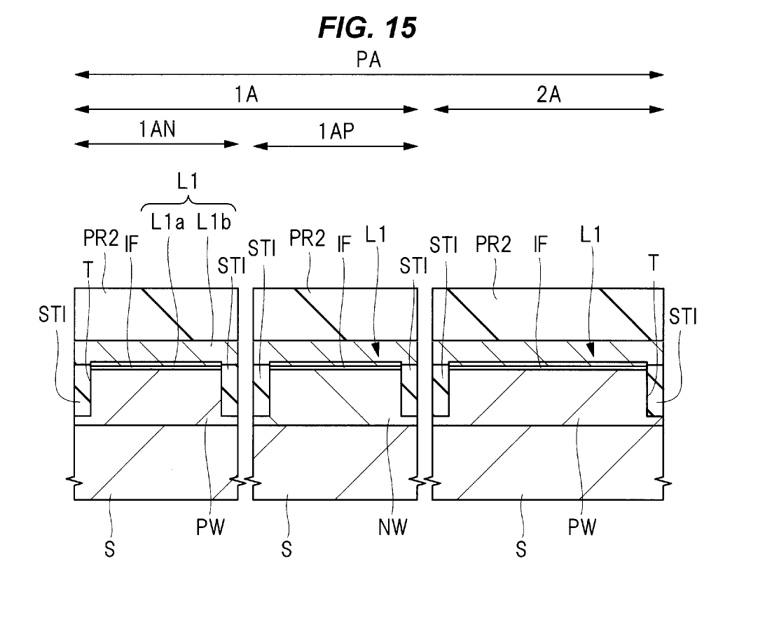

Subsequently, as shown in FIGS. 14 and 15, a polycrystalline or amorphous silicon film L1b is deposited over the element isolation region STI and the silicon film L1a by using the CVD method or the like. Thereby, a silicon film L1 formed of a laminated film including the polycrystalline silicon film L1a and the polycrystalline or amorphous silicon film L1b is formed. The silicon film L1 becomes the first gate 1G.

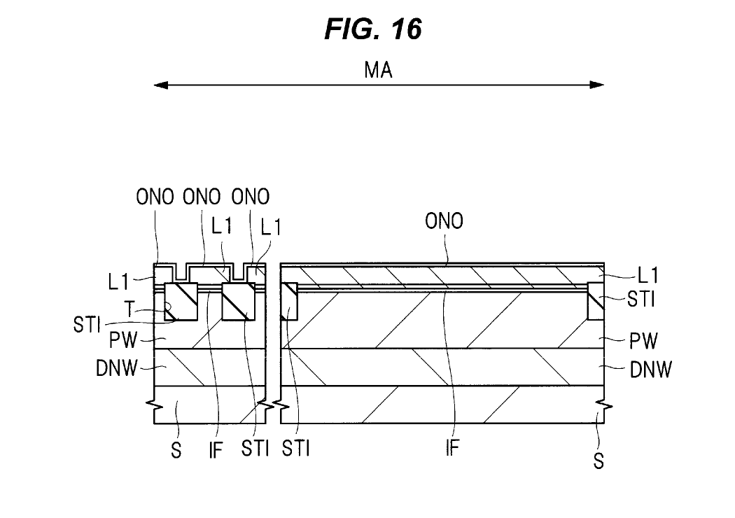

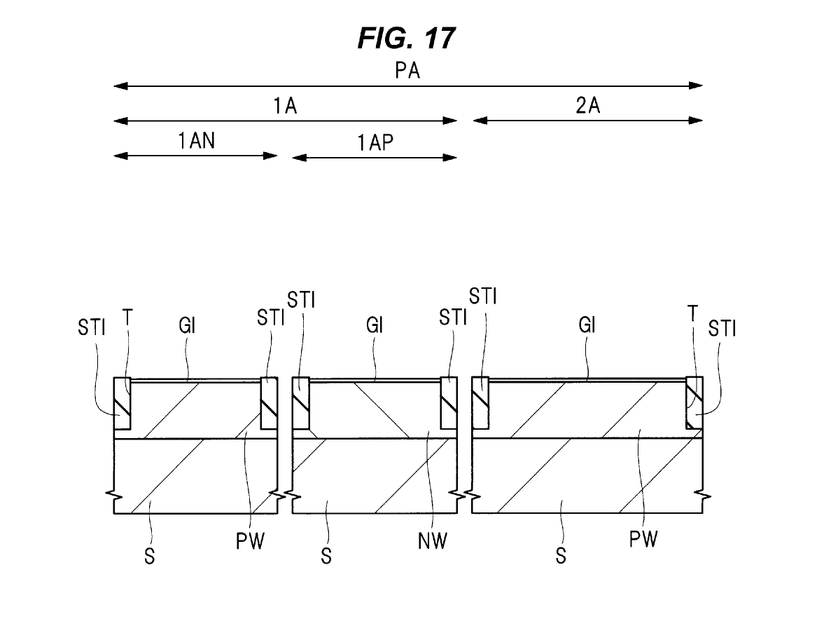

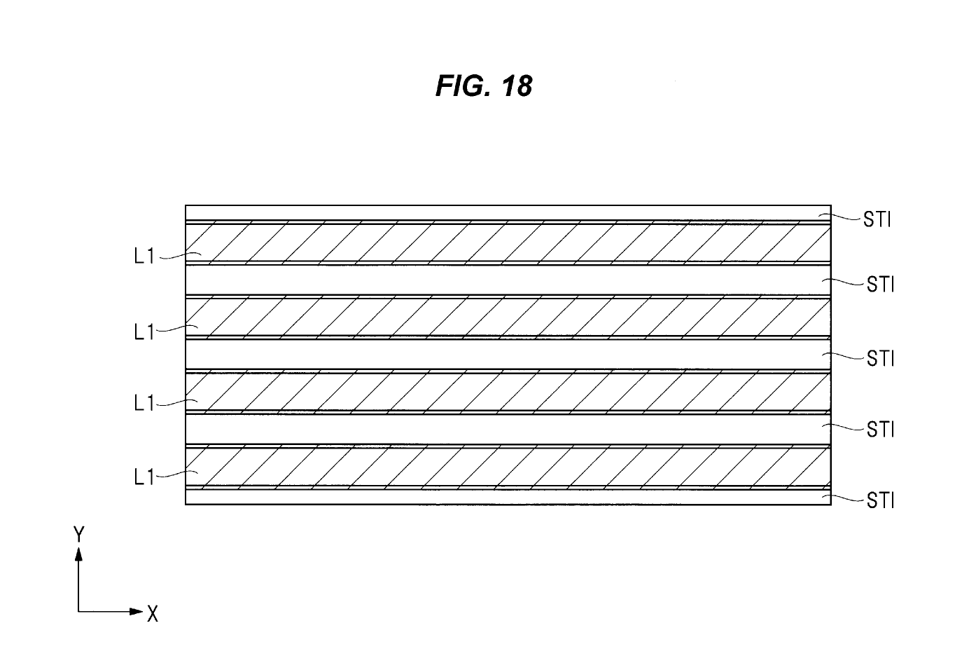

Subsequently, a photoresist film PR2 is formed over the silicon film L1, and the photoresist film PR2 over the element isolation region STI in the memory cell region MA is removed by exposure and development processes. Subsequently, the silicon film L1 is dry-etched by using the photoresist film PR2 as a mask. Thereby, in the memory cell region MA, it is possible to cause the silicon film L1 to remain in a region (active region) between the element isolation regions STI extending in the X direction (FIG. 16). As shown in FIG. 18, a plurality of the silicon films L1 are arranged in a linear shape in the X direction. The silicon film L1 over the peripheral circuit region PA remains without change (FIG. 17). Subsequently, the photoresist film PR2 is removed by ashing.

Subsequently, an insulating film ONO is formed over the silicon film L1 and the element isolation region STI (FIG. 16). For example, a silicon oxide film is formed over the upper surface and the side wall of the silicon film L1 by a thermal oxidation method. Subsequently, a silicon nitride film is deposited over the silicon oxide film by the CVD method or the like. The silicon nitride film becomes a charge accumulation unit of the memory cell and becomes an intermediate layer that forms the insulating film ONO. Subsequently, a silicon oxide film is deposited over the silicon nitride film by the CVD method or the thermal oxidation method. Thereby, the insulating film ONO including the silicon oxide film, the silicon nitride film, and the silicon oxide film can be formed. The insulating film ONO is also formed over the silicon film L1 in the peripheral circuit region PA (not shown in the drawings).

Subsequently, the insulating film ONO and the silicon film L1 over the peripheral circuit region PA are removed by dry etching, and the surface of the semiconductor substrate S (well) is exposed. Subsequently, as shown in FIG. 17, a gate insulating film GI is formed over each region (region 1AN, region 1AP, and I/O region 2A) of the peripheral circuit region PA. For example, a silicon oxide film is formed over each region of the semiconductor substrate S (well) by the thermal oxidation method. The thickness of the silicon oxide film may be changed for each region. The type of the silicon oxide film to be used may be changed for each region.

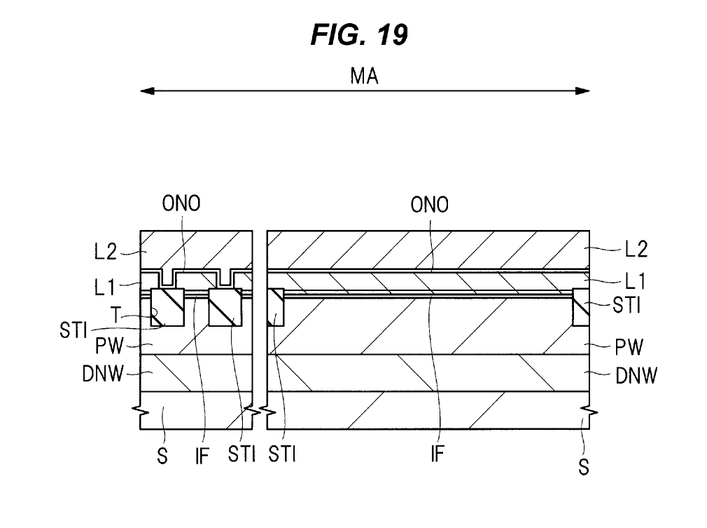

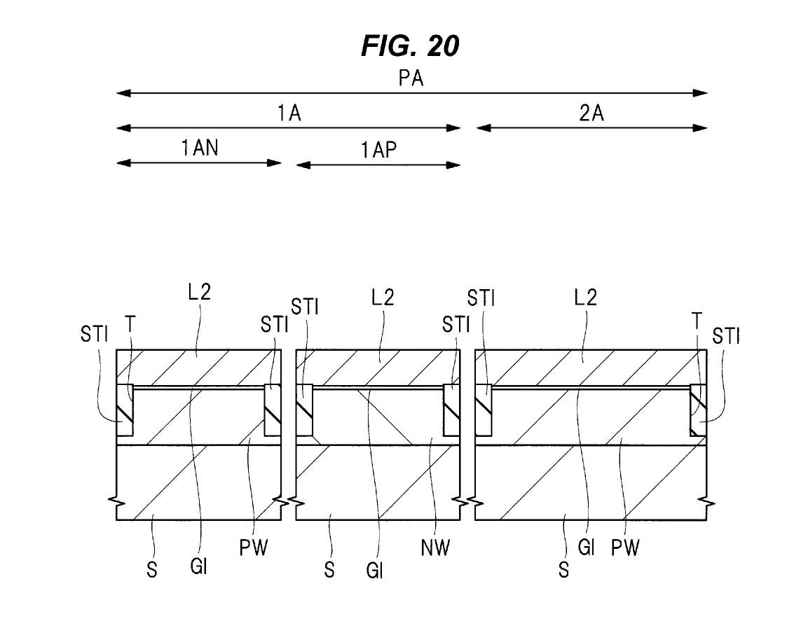

Subsequently, as shown in FIGS. 19 and 20, a polycrystalline silicon film L2 is deposited over the insulating film ONO, the gate insulating film GI, and the element isolation region STI by using the CVD method or the like. The silicon film. L2 becomes the second gate 2G in the memory cell region MA and becomes the gate electrode GE in the peripheral circuit region PA.

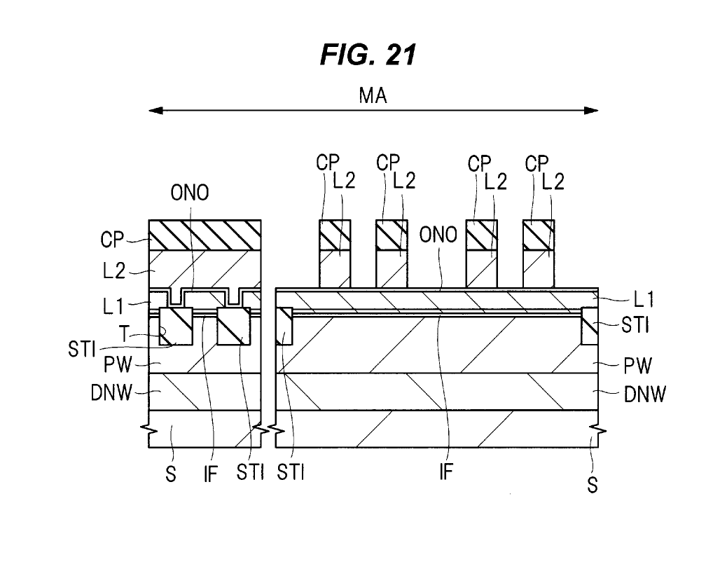

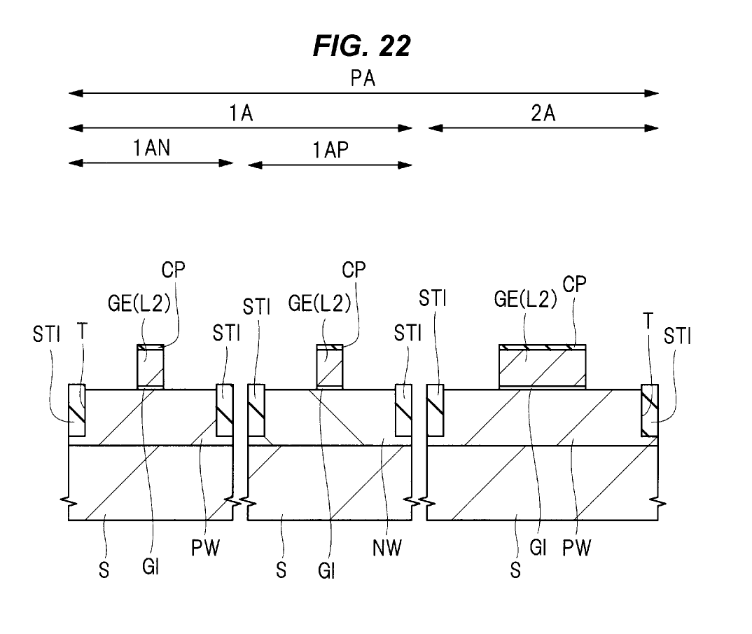

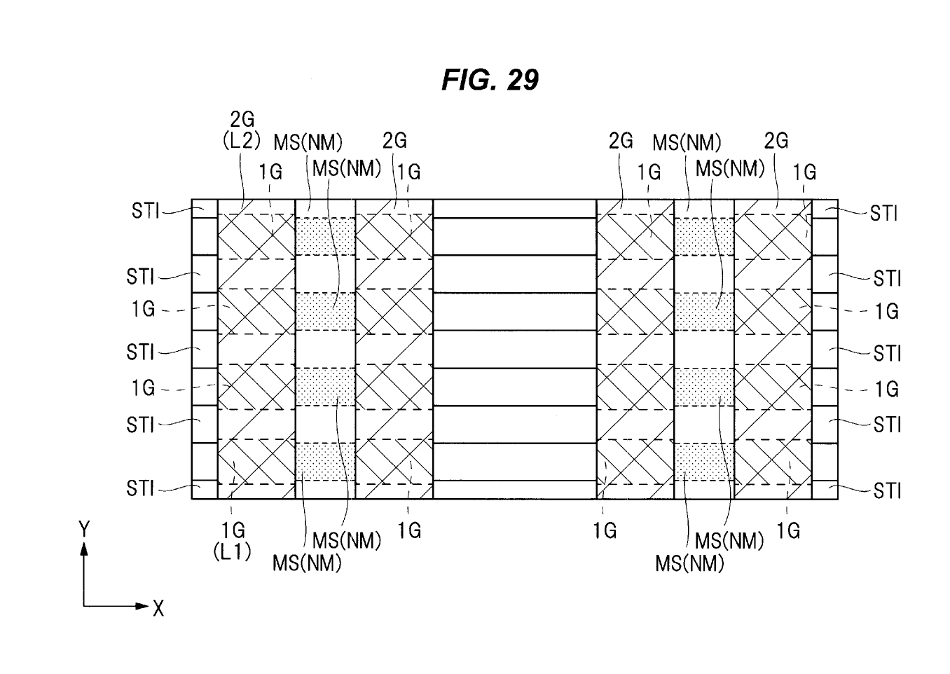

Subsequently, as shown in FIGS. 21 and 22, a silicon oxide film is deposited as a cap insulating film CP over the silicon film L2 by using the CVD method or the like. Subsequently, a photoresist film (not shown in the drawings) is formed over the cap insulating film CP, the photoresist film (not shown in the drawings) having a shape of a plurality of lines extending in the Y direction in the memory cell region MA is caused to remain by exposure and development processes, and the photoresist film (not shown in the drawings) is caused to remain in a region where the gate electrode GE will be formed in the peripheral circuit region PA. Subsequently, the cap insulating film CP is dry-etched by using the photoresist film as a mask. Subsequently, the photoresist film is removed by ashing. Subsequently, the silicon film L2 is dry-etched by using the cap insulating film CP as a mask. Thereby, in the memory cell region MA, the silicon film L2 (the second gate 2G) having a shape of a plurality of lines extending in the Y direction is formed (see FIG. 29).

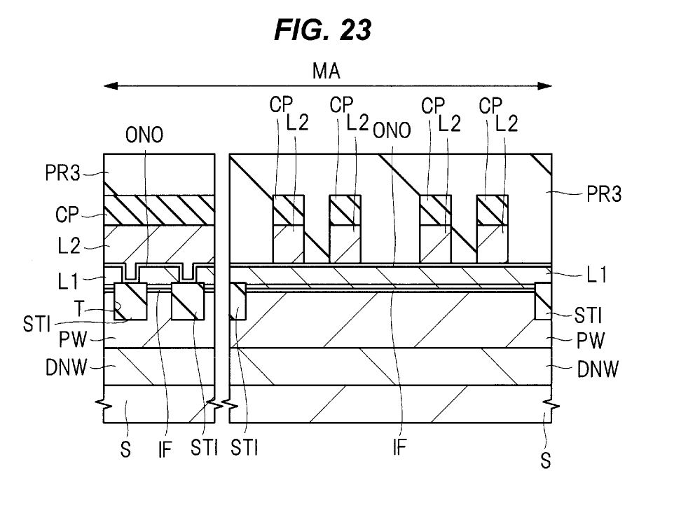

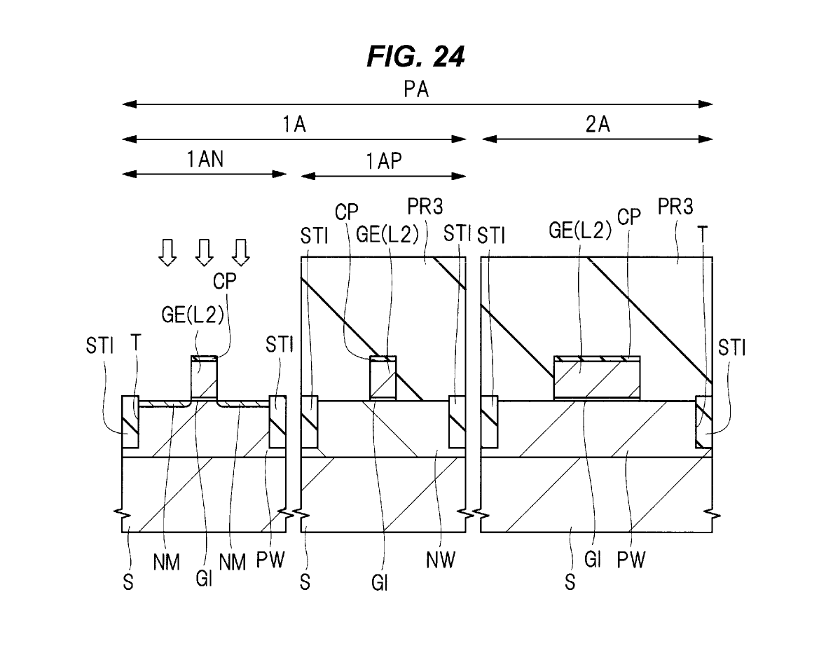

Subsequently, as shown in FIGS. 23 and 24, an n⁻-type semiconductor region NM is formed in a p-type wells PW on both sides of the gate electrode GE in the region 1AN. First, a photoresist film PR3 that covers the memory cell region MA, the region 1AP, and the I/O region 2A is formed. Subsequently, the n⁻-type semiconductor region NM is formed by ion-implanting n-type impurities (for example, phosphorus (P)) into the region 1AN by using the photoresist film PR3 as a mask. For example, the impurity ions in the n⁻-type semiconductor region NM are about 1×10E14/cm². Subsequently, the photoresist film PR3 is removed by ashing.

Subsequently, a photoresist film (not shown in the drawings) that covers the memory cell region MA and the core region 1A is formed, and the n⁻-type semiconductor region NM is formed by ion-implanting n-type impurities (for example, phosphorus (P)) into the I/O region 2A by using the photoresist film as a mask (see FIG. 26). The concentration and the depth of the n⁻-type semiconductor region NM in the region 1AN can be different from those of the n⁻-type semiconductor region NM in the I/O region 2A.

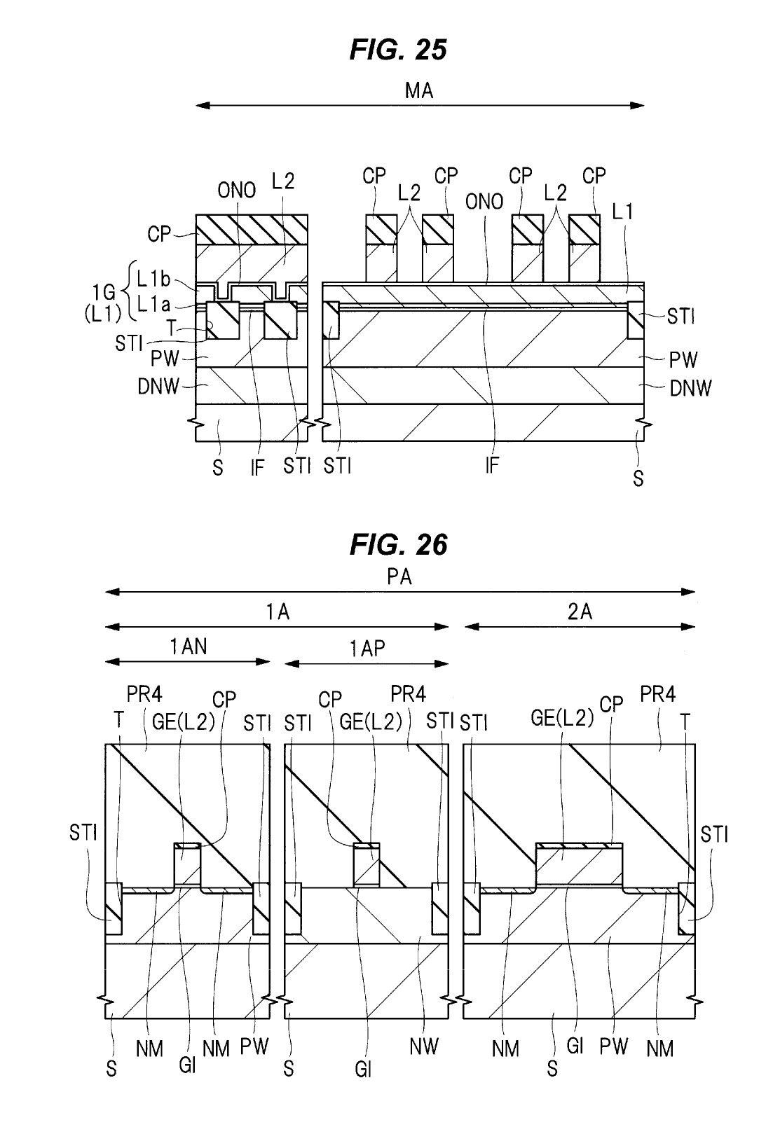

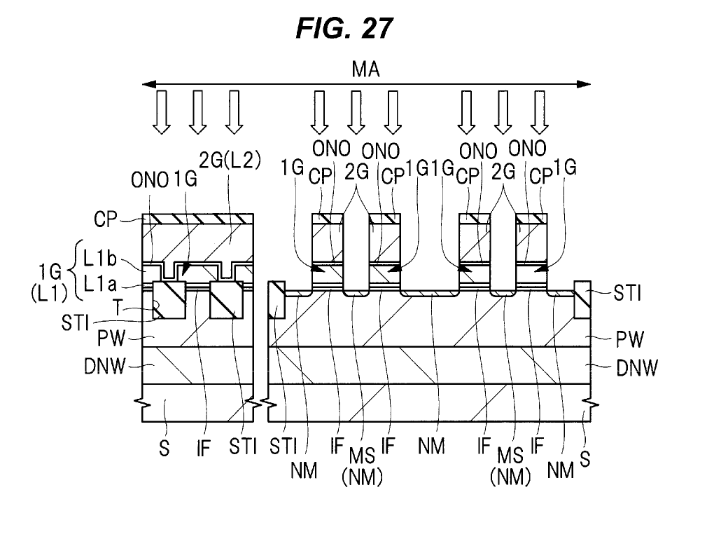

Subsequently, as shown in FIGS. 25 and 26, a photoresist film PR4 that covers the peripheral circuit region PA is formed, and in the memory cell region MA, the insulating film ONO and the silicon film L1 are dry-etched by using the cap insulating film CP and the silicon film L2 as a mask (see FIG. 27). Thereby, the silicon film L1 is divided for each memory cell and the first gate 1G is formed (see FIG. 29). Thereby, the second gates 2G are arranged over a plurality of the first gates 1G as if the second gates 2G couple the first gates 1G arranged in the Y direction. A laminated portion of the first gate 1G and the second gate 2G becomes the laminated gate.

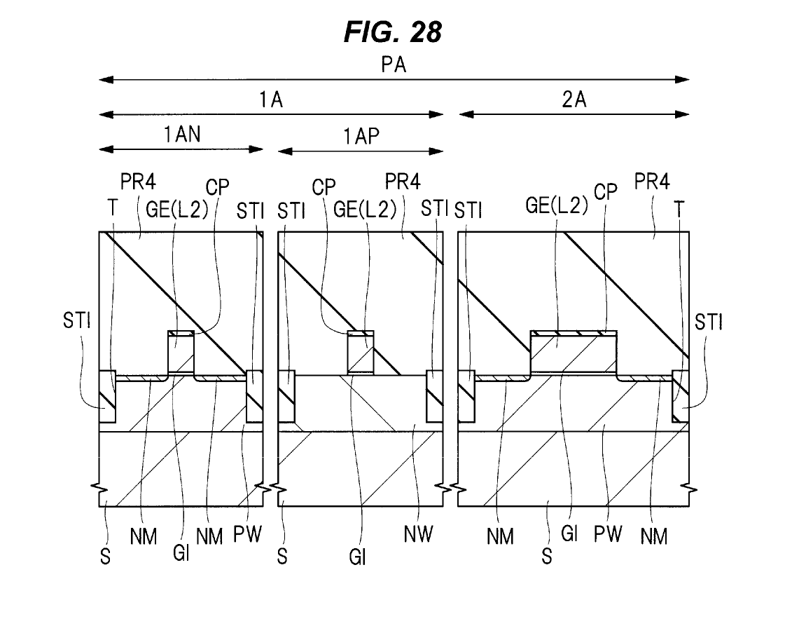

Subsequently, as shown in FIG. 27, an n⁻-type semiconductor region NM (MS) is formed between the laminated gates (1G and 2G). The n⁻-type semiconductor region NM is formed by ion-implanting n-type impurities (for example, phosphorus (P)) into the memory cell region MA by using the photoresist film PR4, the cap insulating film CP, and the laminated gate (1G and 2G) as a mask (FIGS. 27 and 28). However, here, an n⁻-type semiconductor region is also formed in a region where the source region MS is formed. Here, the n⁻-type semiconductor region is referred to as “MS (NM)” for convenience. However, the element isolation region STI is exposed in the back side of the source region (n⁻-type semiconductor region) MS (NM) shown in the right figure in FIG. 27, and n-type impurities are not ion-implanted into the element isolation region STI. Therefore, at this time, the source region (n⁻-type semiconductor region) MS (NM) is not formed into a line shape extending in the Y direction as shown in FIG. 48, but formed into regions sprinkled in the Y direction as shown in FIG. 29.

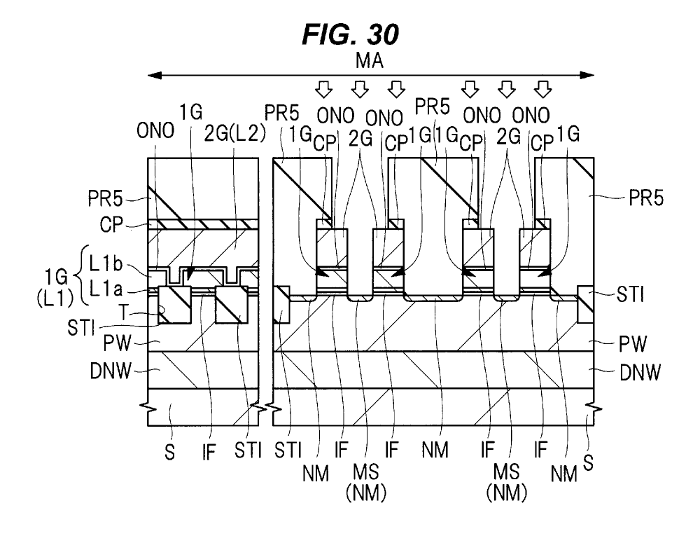

Therefore, as shown in FIGS. 30 to 33, the element isolation region STI between the source regions (n⁻-type semiconductor regions) MS (NM) is removed, and a source region MS having a line shape extending in the Y direction is formed. First, the photoresist film PR4 is removed, and a photoresist film PR5 that linearly opens a portion above a region where the source region MS is formed. In this case, the opening portion of the photoresist film PR5 may be provided to have a width corresponding to a gap between the second gates 2G shown in FIG. 29. However, it is difficult to align the end portion of the second gate 2G and the end portion of the opening portion of the photoresist film PR5, so that the end portion of the opening portion of the photoresist film PR5 is located above the second gate 2G (the cap insulating film CP). Therefore, the opening portion of the photoresist film PR5 has a width greater than the gap between the second gates 2G (FIG. 30). Here, for example, about a half of the gate length (for example, about 0.1 μm to 0.2 μm) of the second gate 2G is covered by the photoresist film PR5.

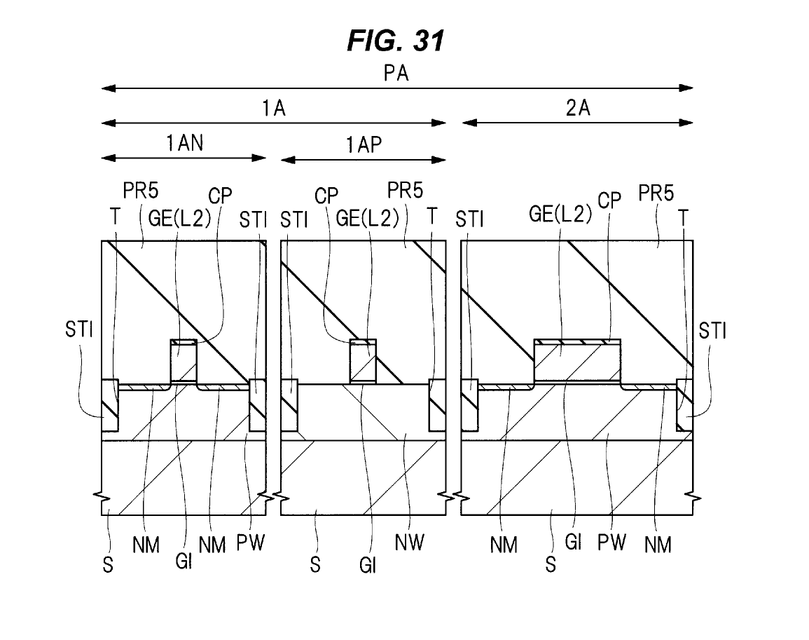

Subsequently, the element isolation region STI in the back side of the source region (n⁻-type semiconductor region) MS (NM) shown in the right figure in FIG. 30 is dry-etched by using the photoresist film PR5 and the laminated gate (1G and 2G) as a mask (FIGS. 30 and 31). The dry etching is etching with depositional characteristics as described with reference to FIG. 1. According to such etching, it is possible to reduce the thickness reduction of the photoresist film and improve the accuracy of the etching. As a gas used for the etching, for example, fluorocarbon gas such as CF₄, CHF₃, CH₂F₂, C₄F₈, C₄F₆, and C₃F₈ can be used. When the gas as described above is used, while a film to be etched is being etched by CF radicals (CF*, CF₂*, and CF₃*), deposit including fluorocarbon-based polymer (CF-based polymer) is deposited over the upper surface and the side surface of the photoresist film as an etching by-product, so that the photoresist film can be protected. The deposit described above may include a film to be etched (here, Si-based compound) that spatters during the etching.

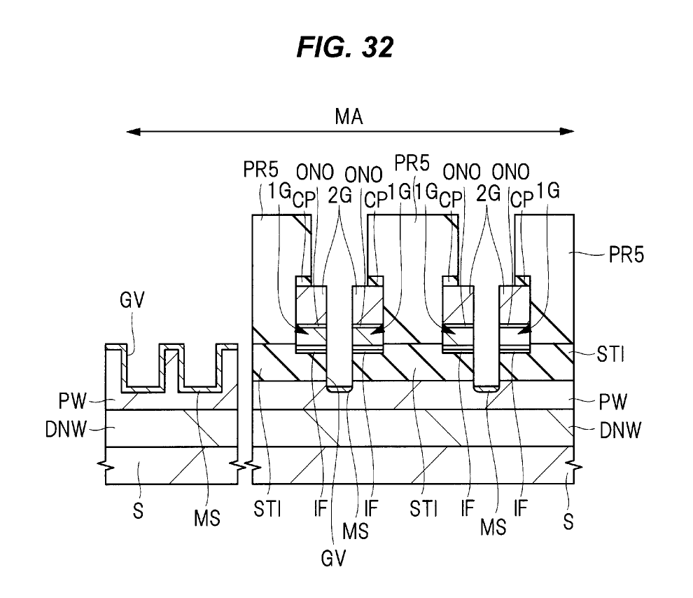

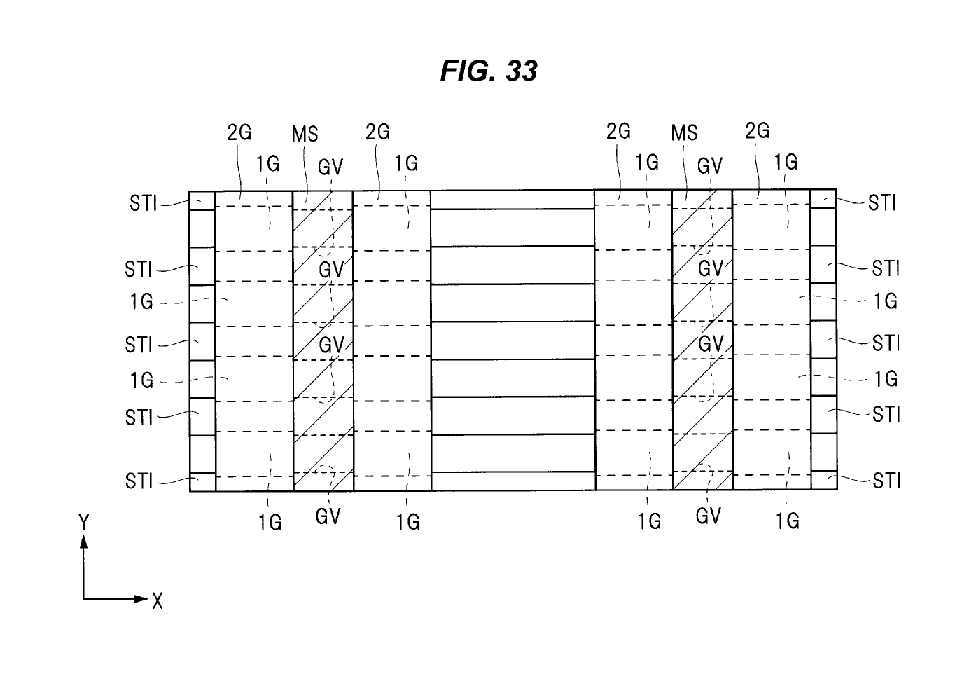

A trench GV is formed by the above etching, and the semiconductor substrate S (p-type well PW) is exposed from the bottom surface and the side surface of the trench GV (FIGS. 32 and 33). In this case, as shown in the left figure in FIG. 32, the semiconductor substrate S (p-type well PW) located between the second gates 2G has a concave-convex shape.

Subsequently, the surface of the photoresist film PR5 is etched (slightly asked). For example, the etching is performed by using oxygen or ozone as an etching gas. Ar may be introduced into an etching atmosphere. It is not necessarily essential to add Ar into the etching gas and apply a substrate bias. However, when elements whose mass number is greater than that of oxygen are added into the etching gas and the substrate bias is applied, a sputtering effect is improved and an etching speed is improved. When the slight ashing is performed on the photoresist film PR5 in this way, it is possible to remove the deposit that is deposited over the surface of the photoresist film PR5 during the dry etching of the element isolation region STI (see FIG. 1).

Subsequently, an n⁺-type semiconductor region (the source region MS) is formed by ion-implanting n-type impurities (for example, phosphorus (P)) into the surface of the semiconductor substrate S (p-type well PW), which is exposed in a concave-convex shape, by using the photoresist film PR5 and the laminated gate (1G and 2G) as a mask (see FIG. 32). In this case, the ion implantation is performed a plurality of times while changing the implantation direction in order to form the n⁺-type semiconductor region not only over the bottom surface of the trench GV, but also over the side surface of the trench GV. The impurity ions in the n⁺-type semiconductor region are, for example, about 1×10E15/cm². Thereby, the source region MS extending in the Y direction is formed between the laminated gates (1G and 2G) (see FIG. 33 and the left figure in FIG. 32).

Subsequently, the photoresist film PR5 is removed by ashing. In the ashing, as described above, carbon (C) and hydrogen (H), which are main components of the photoresist film, react with oxygen (O₂) to form CO₂, CO, and H₂O (water vapor) and they are vaporized. The ashing condition is the same as that of the photoresist films (for example, PR1 to PR4) that have been formed, and is the same as that of the photoresist films (for example, PR6 to PR8) that will be formed. Here, even when a bias potential is not applied to the substrate, the ashing process progresses quickly. However, as an ashing condition, Ar may be added to the gas and the bias potential may be applied to the substrate.

As described above, according to the present embodiment, after the etching process with depositional characteristics is performed, the slight ashing is performed, and then after the deposit that is deposited over the surface of the photoresist film PR5 is removed, the ion implantation of impurities is performed, so that it is possible to accurately perform the ashing of the photoresist film PR5. For example, as described with reference to FIG. 2, it is possible to prevent a hardened layer from being formed due to injection of impurity ions into the deposit over the surface of the photoresist film PR5. As a result, it is possible to suppress the explosion (the popping phenomenon) of the photoresist film under the hardened layer, so that it is possible to prevent the hardened layer and the photoresist film from spattering and prevent the pattern of the laminated gate and the gate electrode from being broken.

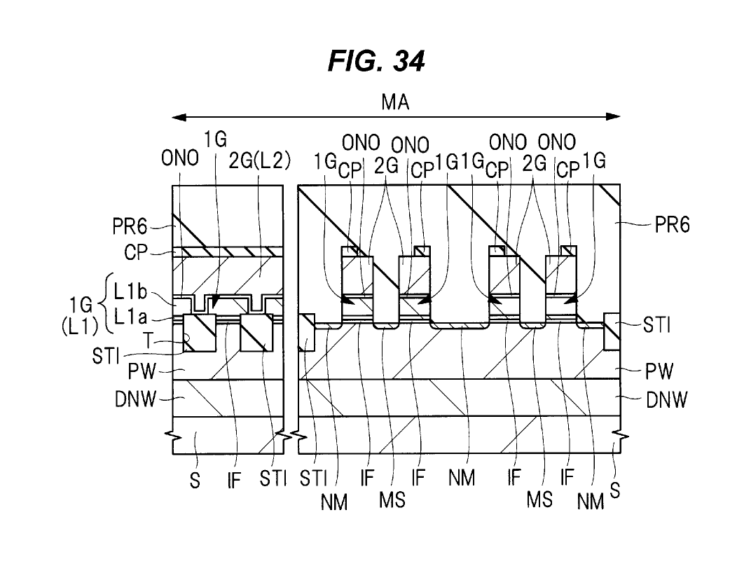

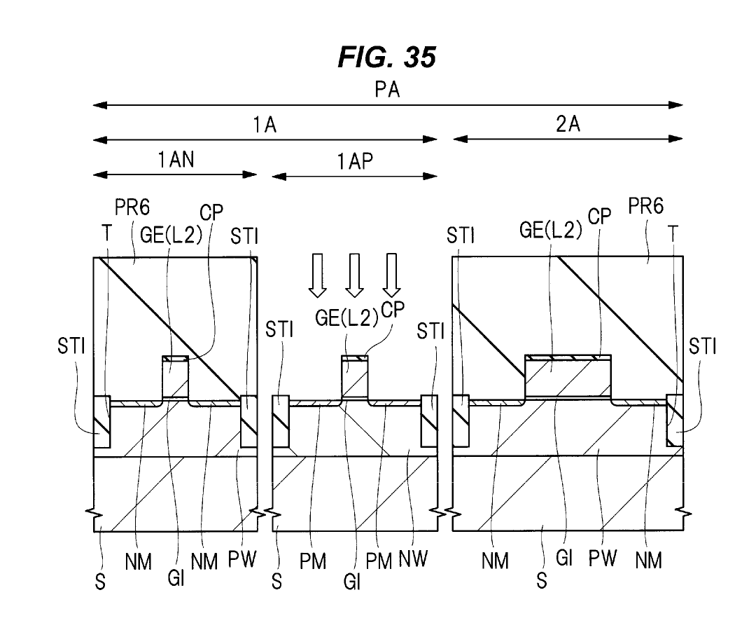

Subsequently, as shown in FIGS. 34 and 35, a p⁻-type semiconductor region PM is formed in an n-type wells NW on both sides of the gate electrode GE in the region 1AP. First, a photoresist film PR6 that covers the memory cell region MA, the region 1AN, and the I/O region 2A is formed. Subsequently, the p⁻-type semiconductor region PM is formed by ion-implanting p-type impurities (for example, boron (B)) into the region 1AP by using the photoresist film PR6 as a mask. Subsequently, the photoresist film PR6 is removed by ashing. For example, the process is performed in the same condition as that of the ashing of the photoresist film PR5.

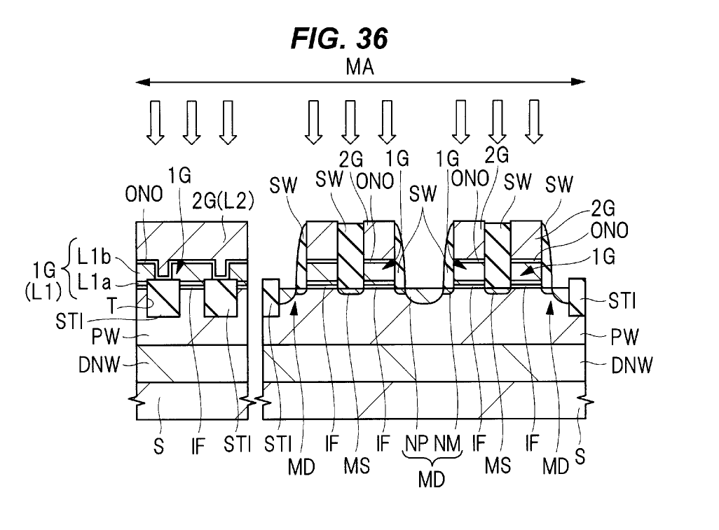

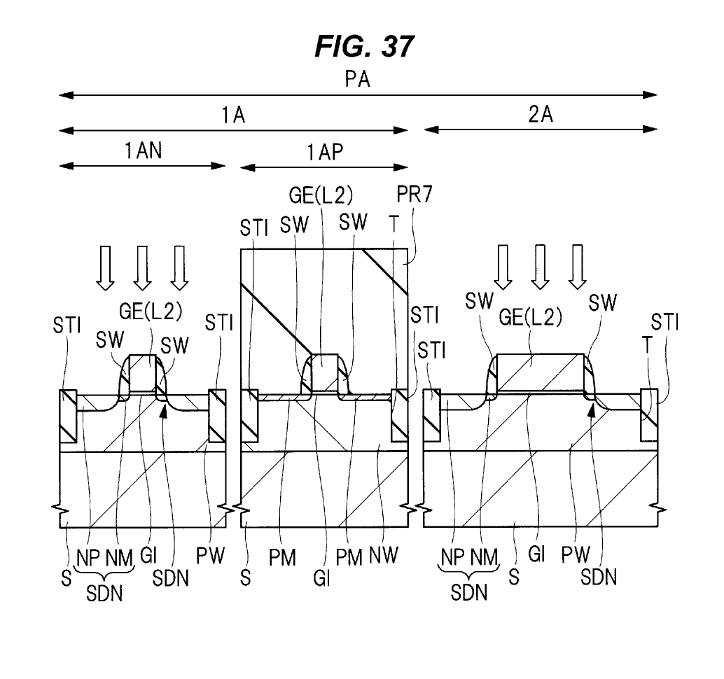

Subsequently, as shown in FIGS. 36 and 37, an n⁺-type semiconductor region NP that forms the drain region MD in the memory cell region MA and an n⁺-type semiconductor region NP that forms the source/drain region SDN in the region 1AN and the I/O region 2A are formed. First, a side wall insulating film SW is formed over the side wall portion of the laminated gate (1G and 2G) and the gate electrode GE. For example, a silicon oxide film is deposited over the semiconductor substrate S by using the CVD method or the like. The silicon oxide film is removed by a predetermined thickness from the surface thereof by anisotropic dry etching, so that the side wall insulating film SW is formed over the side wall portion of the laminated gate (1G and 2G) and the gate electrode GE. Subsequently, the photoresist film PR7 that covers the region 1AP is formed. Subsequently, an n⁺-type semiconductor region NP is formed by implanting n-type impurities (for example, phosphorus (P)) by using the photoresist film PR7, the laminated gate (1G and 2G), the gate electrode GE, and the side wall insulating film SW as a mask. In this case, the n⁺-type semiconductor region NP is formed by being self-aligned to the side wall insulating film SW. The impurity concentration of the n⁺-type semiconductor region NP is higher than that of the n⁻-type semiconductor region NM and the junction depth of the n⁺-type semiconductor region NP is greater than that of the n⁻-type semiconductor region NM. By this process, the drain region MD including the n⁻-type semiconductor region NM and the n⁺-type semiconductor region NP is formed and the source/drain region SDN including the n⁻-type semiconductor region NM and the n⁺-type semiconductor region NP is formed. Subsequently, the photoresist film PR7 is removed by ashing.

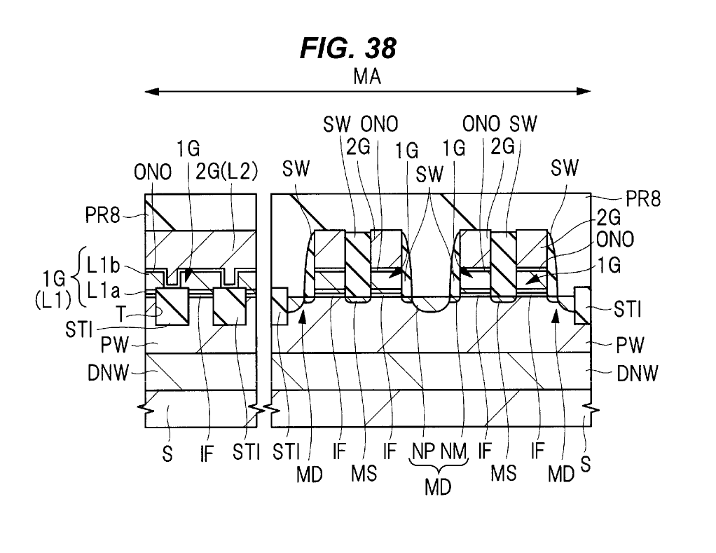

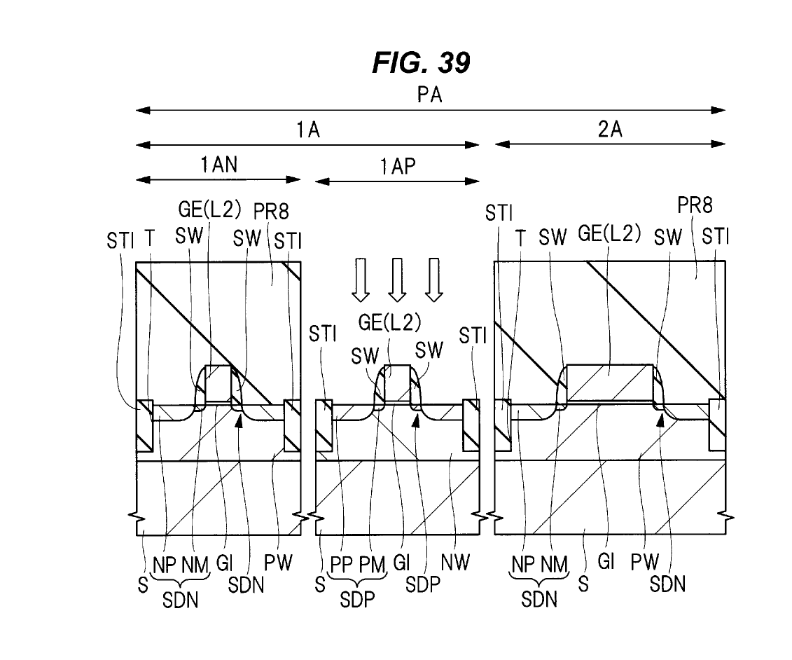

Subsequently, as shown in FIGS. 38 and 39, a photoresist film PR8 that covers the memory cell region MA, the region 1AN, and the I/O region 2A is formed. Subsequently, the p⁺-type semiconductor region PP is formed by ion-implanting p-type impurities (for example, boron (B)) into the region 1AP by using the photoresist film PR8, the gate electrode GE, and the side wall insulating film SW as a mask. In this case, the p⁺-type semiconductor region PP is formed by being self-aligned to the side wall insulating film SW. The impurity concentration of the p⁺-type semiconductor region PP is higher than that of the p⁻-type semiconductor region PM and the junction depth of the p⁺-type semiconductor region PP is greater than that of the p⁻-type semiconductor region PM. By this process, the source/drain region SDP including the p⁻-type semiconductor region PM and the p⁺-type semiconductor region PP is formed. Subsequently, the photoresist film PR8 is removed by ashing.

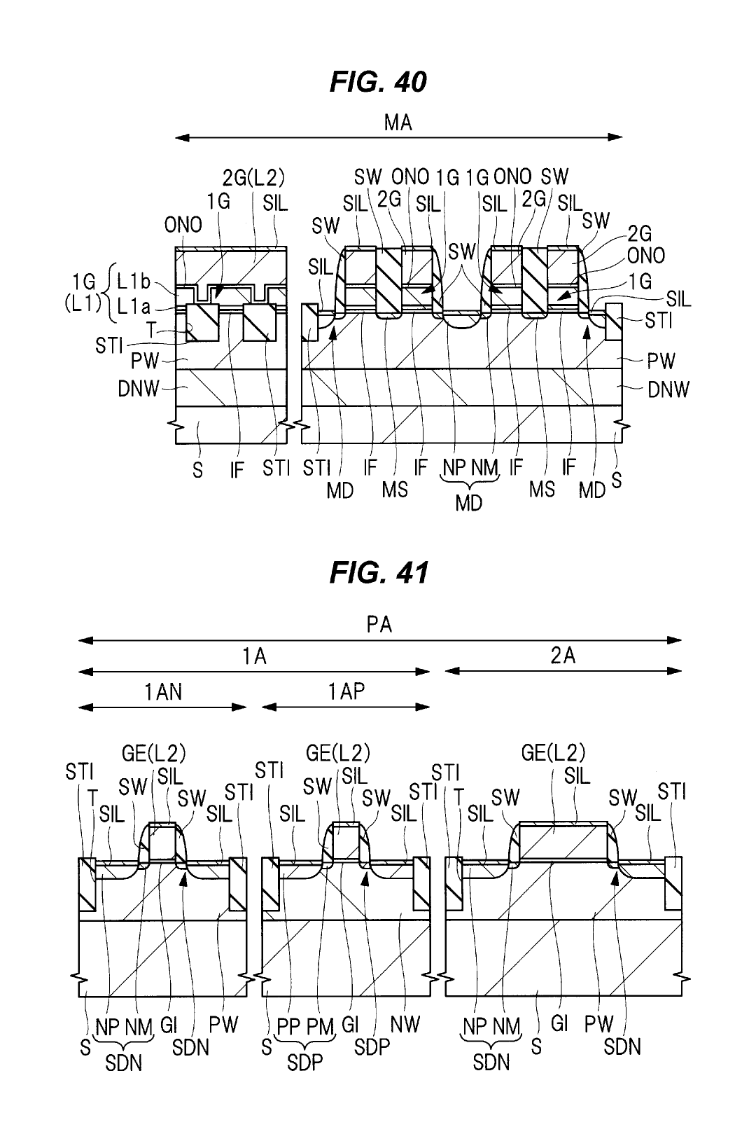

Subsequently, as shown in FIGS. 40 and 41, a metal silicide film SIL is formed over the laminated gate (1G and 2G), the source region MS, the drain region MD, the gate electrode GE, and the source/drain regions SDN and SDP by using a salicide technique. For example, a metal film (not shown in the drawings) is formed over the semiconductor substrate S and a heat treatment is performed on the semiconductor substrate S, so that the metal film is reacted with the laminated gate (1G and 2G), the source region MS, the drain region MD, the gate electrode GE, and the source/drain regions SDN and SDP. Thereby, the metal silicide film SIL is formed over each of the laminated gate (1G and 2G), the source region MS, the drain region MD, the gate electrode GE, and the source/drain regions SDN and SDP. The metal film is formed of, for example, nickel (Ni), nickel-platinum (Pt) alloy, and the like and can be formed by a sputtering method or the like. Subsequently, the metal film that has not reacted is removed. The diffusion resistance and the contact resistance can be reduced by the metal silicide film SIL.

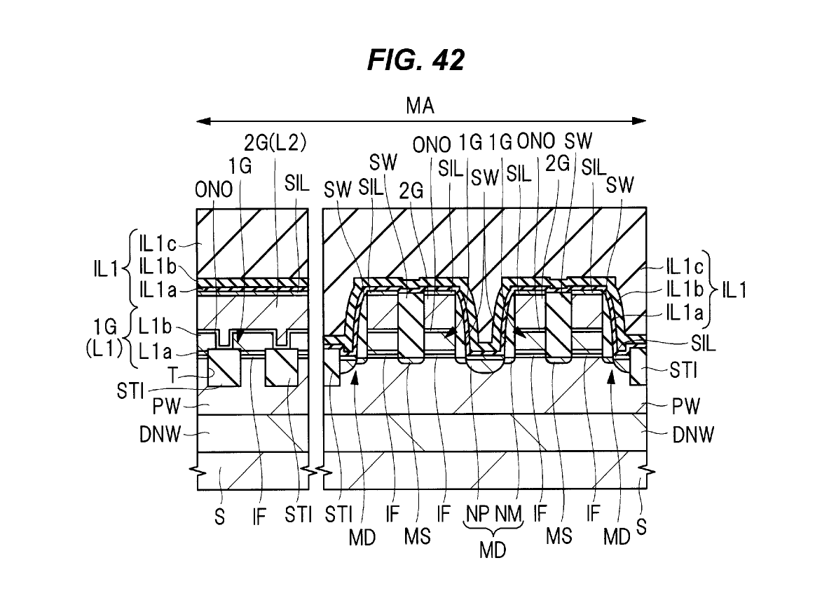

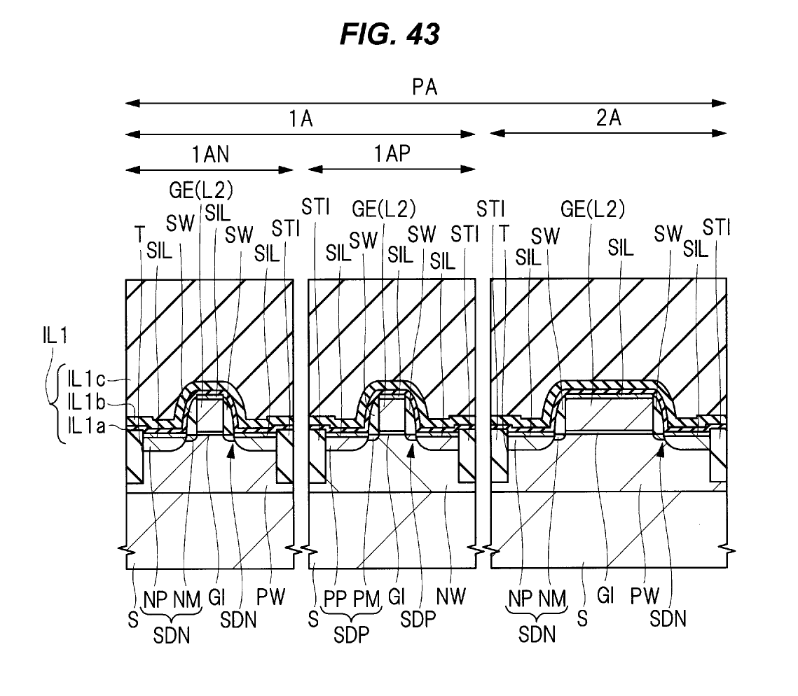

Subsequently, as shown in FIGS. 42 and 43, an interlayer insulating film IL1 is formed over the laminated gates (1G and 2G) and the gate electrode GE. For example, an NSG film (a silicon oxide film that does not contain impurities such as phosphorus and boron) is formed as a thin oxide film IL1a over the laminated gates (1G and 2G) and the gate electrode GE by the CVD method or the like and a silicon nitride film IL1b is formed over the NSG film by the CVD method or the like. The process to form the thin oxide film IL1a may be omitted, and the silicon nitride film IL1b may be formed directly. Subsequently, a thick silicon oxide film IL1c is formed over the silicon nitride film IL1b by the CVD method or the like. Thereby, it is possible to form the interlayer insulating film IL1 including the oxide film IL1a, the silicon nitride film IL1b, and the silicon oxide film IL1c over the laminated gate (1G and 2G) and the gate electrode GE.

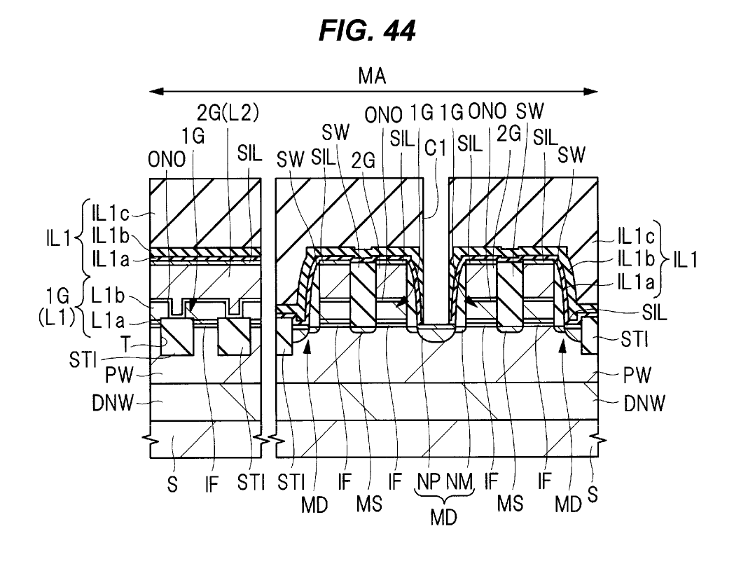

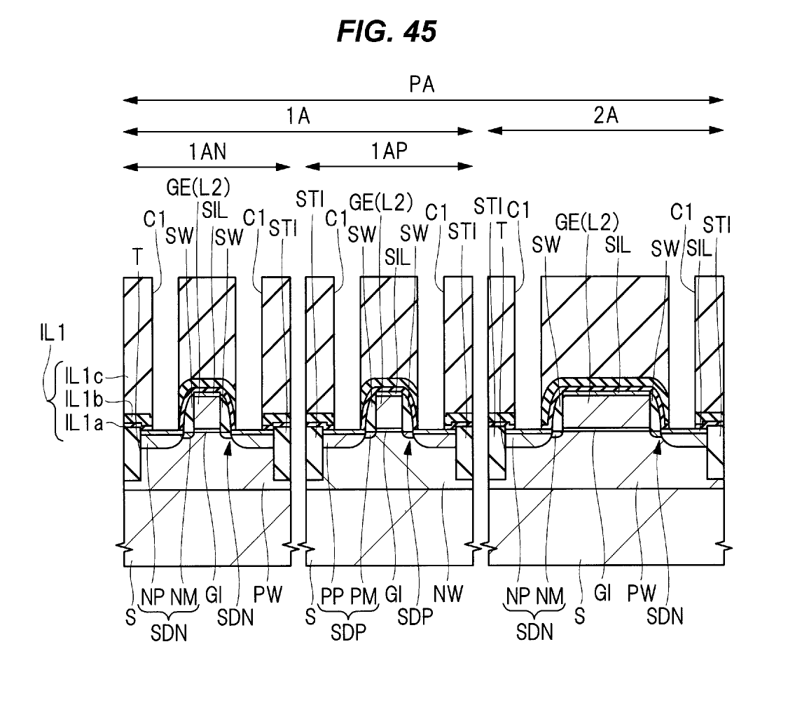

Next, as shown in FIGS. 44 and 45, a contact hole C1 is formed by selectively removing the interlayer insulating film IL1. For example, a photoresist film (not shown in the drawings) is formed over the interlayer insulating film. IL1, and for example, the photoresist film over the drain region MD and the source/drain regions SDN and SDP is removed. Subsequently, the interlayer insulating film IL1 is dry-etched by using the photoresist film as a mask. Subsequently, the photoresist film is removed by ashing.

Subsequently, as shown in FIGS. 46 to 48, a plug P1 is formed in the interlayer insulating film IL1, and further, a wiring M1 is formed over the interlayer insulating film IL1 and the plug P1. For example, the plug P1 is formed by burying a conductive film in the contact hole (C1) in the interlayer insulating film. Subsequently, a conductive film is deposited over the interlayer insulating film IL1 and the conductive film is patterned, so that the wiring M1 is formed. Thereafter, two or more layers of wiring may be formed by repeating the forming process of the interlayer insulating film, the plug, and the wiring.

It is possible to form the semiconductor device of the present embodiment by the process described above. According to the process described above, the removing process of the element isolation region STI and the ion implantation process for forming the source region MS are performed by using the same photoresist film PR5, so that it is possible to form the semiconductor device in a process shorter than that in a case where a photoresist film is formed in each process. When the photoresist film is formed again in the ion implantation process, there is a risk that a mask misalignment occurs, and for example, a problem may occur in which sufficient impurity ions are not implanted into a region into which impurity ions should be implanted. On the other hand, as in the present embodiment, the removing process of the element isolation region STI and the ion implantation process for forming the source region MS are performed by using the same photoresist film PR5, so that it is possible to avoid the mask misalignment as described above and form a semiconductor device having excellent characteristics.

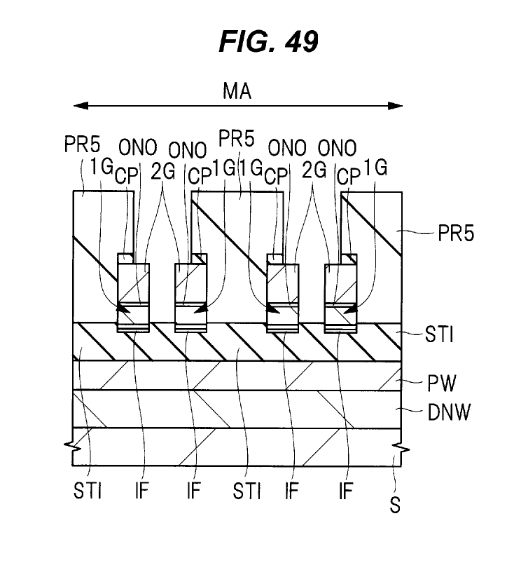

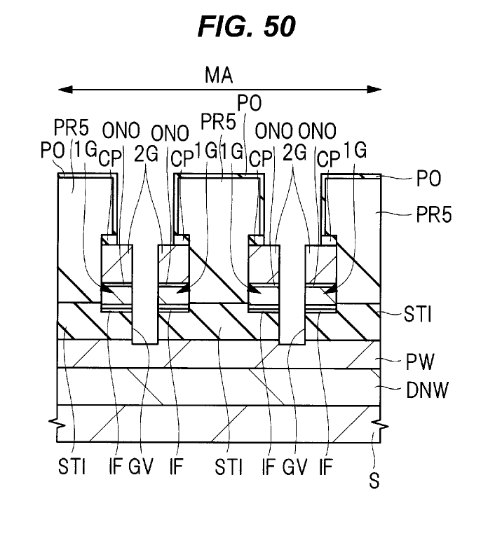

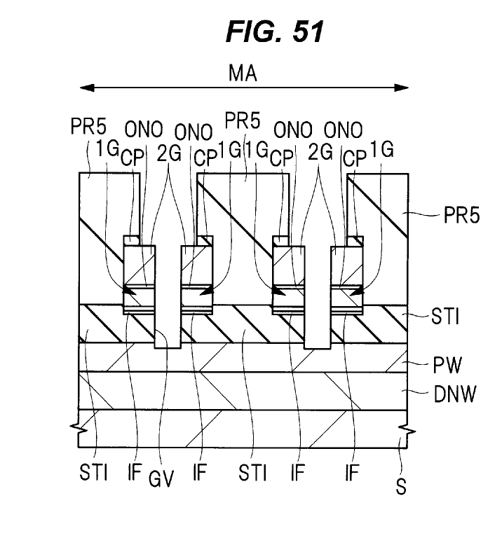

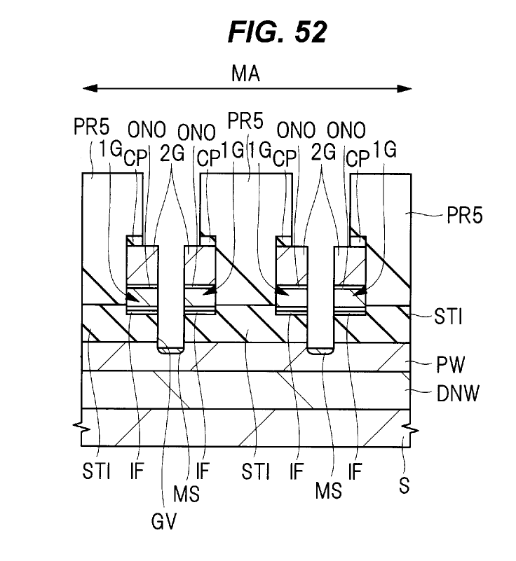

Further, as described above, according to the present embodiment, it is possible to suppress the popping phenomenon of the photoresist film PR5 and form a semiconductor device having excellent characteristics. Further, it is possible to improve the yield rate of the semiconductor device. FIGS. 49 to 52 selectively show a characteristic manufacturing process of the present embodiment. That is, when the element isolation region STI is etched by using the photoresist film PR5 as a mask (FIG. 49), the deposit PO (FIG. 50) formed over the surface of the photoresist film. PR5 is removed by slight ashing (FIG. 51), and thereafter the source region (n⁺-type semiconductor region) MS is formed by ion implantation (FIG. 52), so that it is possible to suppress the popping phenomenon of the photoresist film. PR5 during ashing. As described above, it is preferable that the slight ashing is performed in a range between 50 nm and 300 nm of the amount of slight ashing (the amount of etching).

### STUDY EXAMPLE

Hereinafter, experimental results studied by the inventors will be described.

### Study Example 1

For example, in a TEG (test element group) region, a photoresist film is formed in the same manner as in a chip region, polymer etching is performed in the chip region in a state in which no opening is formed in the TEG region, and ions are implanted into the entire surface. In this case, the photoresist film (including a hardened layer and a deposition layer) is formed in the entire surface of the TEG region, so that a structure is formed where the popping phenomenon easily occurs. When the photoresist film of such a semiconductor substrate was ashed, gate breakdown in the TEG region was observed. In this way, the relationship between the ashing and the breakdown of the gate is confirmed.

### Study Example 2

Experiments were performed by changing the amount of slight ashing (for example, 0 nm (REF), 117 nm (AP2), 219 nm (AP4)). It was confirmed that the longer the slight ashing time, the smaller the number of broken gates as compared with a case in which the slight ashing is not performed. For example, the number of broken gates could be reduced to about 1/20 as compared with a case in which the slight ashing is not performed.

### Study Example 3

The thickness of the remaining photoresist film was studied when the photoresist film was processed by changing the amount of slight ashing (for example, 0 nm (REF), 117 nm (AP2), 219 nm (AP4)). When observing cross sections, it was confirmed that film thicknesses sufficient to function as a mask of ion implantation remained.

### Study Example 4

Various characteristics of semiconductor devices manufactured by changing the amount of slight ashing (for example, 0 nm (REF), 117 nm (AP2), and 219 nm (AP4)) were studied. It was confirmed that the semiconductor devices had the same electrical characteristics as those of a semiconductor device manufactured without performing the slight ashing (0 second (REF)). In other words, it was not possible to observe a side effect such that impurity ions are implanted into an undesired position (ion implantation leakage) due to shortage of remaining film of the photoresist film and the electrical characteristics degrade.

### Study Example 5

Experiments were performed by changing the amount of slight ashing (for example, 0 nm (REF), 117 nm (AP2), 219 nm (AP4)). It was confirmed that the longer the slight ashing time, the higher the yield rate in manufacturing products.

### Study Example 6

It was confirmed that when the amount of slight ashing is 334 nm, the thickness of the remaining photoresist film becomes thin and ion implantation leakage occurs as a side effect.

In this way, effects of implanting impurity ions after removing deposit that is deposited over the surface of the photoresist film by the slight ashing could be confirmed. Further, an optimal condition that ensures process margin could be found by confirming the limitations of the remaining photoresist film. The present embodiment is not limited to various conditions based on the study examples. Further, the value of the amount of ashing in this case may vary with respect to the effects and the limitations of the ashing based on the initial thickness of the photoresist film, so that the value is not quantitatively limited.

### Second Embodiment

In the present embodiment, the slight ashing of the photoresist film described in the First Embodiment is not performed, and the popping phenomenon of the photoresist film PR5 is suppressed by changing the ashing condition of the photoresist film. The configuration of the semiconductor device of the present embodiment is the same as that of the First Embodiment. Regarding the manufacturing process of the semiconductor device of the present embodiment, processes different from those in the First Embodiment will be described in detail.

### [Description of Structure]

The configuration of the semiconductor device of the present embodiment is the same as that of the First Embodiment, so that the description thereof will be omitted (see FIGS. 46 to 48).

### [Description of Manufacturing Method]

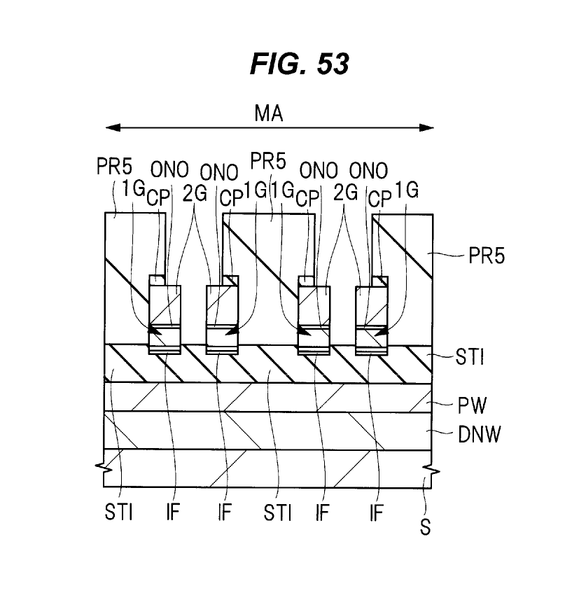

The processes from the start to the process to form the n⁻-type semiconductor region NM between the laminated gates (1G and 2G), which are described with reference to FIGS. 3 to 29 in the First Embodiment, are the same as those in the First Embodiment, so that the description thereof will be omitted. FIGS. 53 to 56 are cross-sectional views showing the manufacturing process of the semiconductor device of the present embodiment.

After the processes described above, the element isolation region STI between the source regions (n⁻-type semiconductor regions) MS (NM) is removed, and a source region MS having a line shape extending in the Y direction is formed (see FIGS. 30 to 33). However, in the present embodiment, the slight ashing of the photoresist film PR5 described in the First Embodiment is not performed, and the popping phenomenon is suppressed by changing the ashing condition of the photoresist film PR5.

Specifically, as shown in FIG. 53, the photoresist film PR5 that linearly opens a portion above a region where the source region MS is formed. At this time, an end portion of the opening portion of the photoresist film PR5 is located above the second gate 2G. Therefore, the opening portion of the photoresist film PR5 has a width greater than the gap between the second gates 2G (FIG. 53). Here, for example, about a half of the gate length of the second gate 2G is covered by the photoresist film PR5.

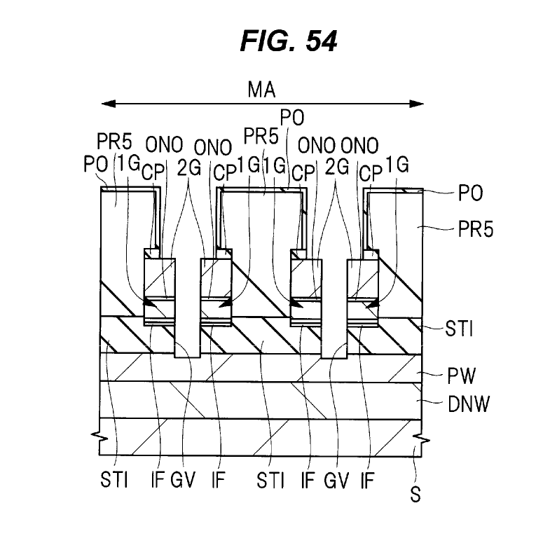

Subsequently, the element isolation region STI is dry-etched by using the photoresist film PR5 and the laminated gate (1G and 2G) as a mask. The dry etching is etching with depositional characteristics as described in detail in the First Embodiment. In this case, as shown in FIG. 54, the deposit PO is formed over the surface of the photoresist film PR5.

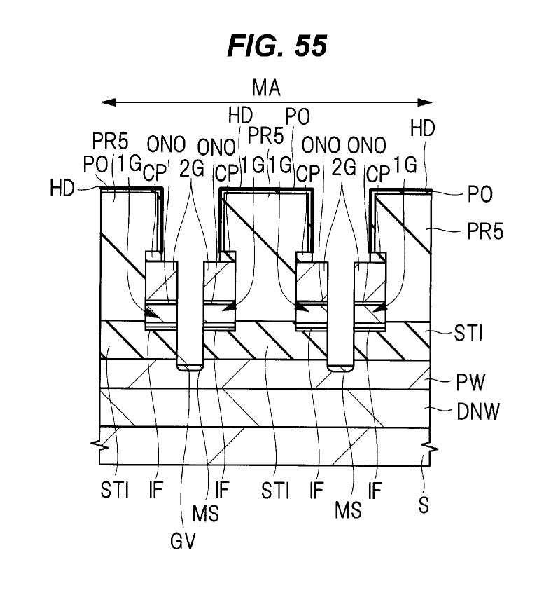

Subsequently, as shown in FIG. 55, an n⁺-type semiconductor region (the source region MS) is formed by ion-implanting n-type impurities (for example, phosphorus (P)) into the surface of the semiconductor substrate S (p-type well PW) by using the photoresist film PR5 where the deposit PO is formed over its surface and the laminated gate (1G and 2G) as a mask. In this case, the ion implantation is performed a plurality of times while changing the implantation direction in the same manner as in the First Embodiment. The dose amount of the impurity ions in the n⁺-type semiconductor region are, for example, about 1×10E15/cm². Thereby, the source region MS extending in the Y direction is formed between the laminated gates (1G and 2G) (see FIG. 33 and the left figure in FIG. 32). When the ion implantation is performed in a state in which the deposit PO is formed over the surface of the photoresist film PR5 in this way, the impurity ions are also implanted into the deposit PO and a hardened layer (an altered layer) HD is formed (see FIG. 55).

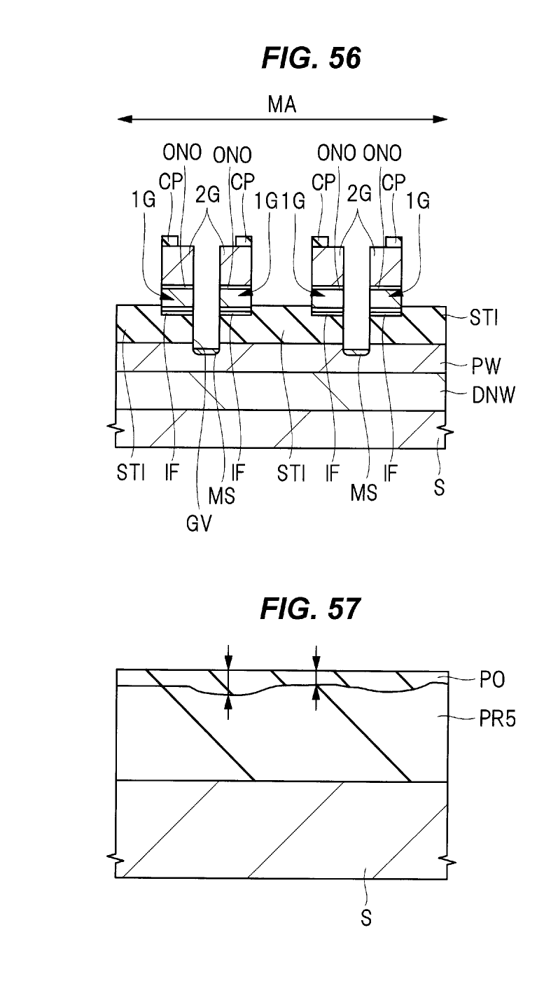

Subsequently, as shown in FIG. 56, the photoresist film PR5 is removed by low temperature ashing. Specifically, the ashing of the photoresist film PR5 is performed at a temperature lower than the ashing temperature of the photoresist films (for example, PR1 to PR4) that have been formed or the ashing temperature of the photoresist films (for example, PR6 to PR8) that will be formed. For example, the ashing temperature is set to 110° C. to 120° C. (110° C. or more and 120° C. or less). The ashing is performed by using oxygen or ozone as an ashing gas. As an ashing condition, Ar may be added to the gas and a bias potential may be applied to the substrate. When elements whose mass number is greater than that of oxygen are added into the ashing gas and the substrate bias is applied in this way, a sputtering effect is improved and an ashing speed is improved.

As described above, according to the present embodiment, the ashing temperature of the photoresist film PR5 is set to a relatively low temperature, for example, a temperature lower than the ashing temperature of the photoresist films (for example, PR1 to PR4) that have been formed or the ashing temperature of the photoresist films (for example, PR6 to PR8) that will be formed, so that it is possible to suppress the popping phenomenon of the photoresist film. The ashing speed of the photoresist film. PR5 of the present embodiment is slower than, for example, the ashing speed of the photoresist films (for example, PR1 to PR4) that have been formed or the ashing speed of the photoresist films (for example, PR6 to PR8) that will be formed.

In this way, even when the ashing is performed in a state in which the surface of the photoresist film PR5 is covered by the hard hardened layer HD, it is possible to reduce the expansion rate of vaporized gas in the photoresist film and suppress the internal pressure inside the photoresist film by performing the ashing at a relatively low temperature. Therefore, it is possible to suppress the popping phenomenon.

Thereafter, the same process as that in the First Embodiment is performed, so that the semiconductor device of the present embodiment can be formed (see FIGS. 34 to 49).

### Study Example

Hereinafter, experimental results studied by the inventors will be described. For example, in the TEG region, when the photoresist film PR5 where the hardened layer is formed was ashed (removed) at a temperature around 110° C. to 120° C. in a state in which no opening portion is formed, gate breakdown was not observed. Further, reduction of ashing residue could be confirmed. Further, the yield rate was improved.

### Third Embodiment

In the present embodiment, application examples that can be applied to the process of the etching of the element isolation region STI->the slight ashing of the photoresist film->the ion implantation->the ashing of the photoresist film, which is described in the First Embodiment, will be described.

### Application Example 1

The low temperature ashing described in the Second Embodiment may be applied to the ashing of the photoresist film PR5 described in the First Embodiment. In the First Embodiment, at least some of the deposit PO over the surface of the photoresist film PR5 is removed by the slight ashing. However, a case can be considered in which the deposit PO partially remains or the deposit PO becomes a thin film and remains. In particular, as described in an application example 2 described later, the thickness of the deposit PO varies within the surface of the semiconductor substrate S or varies in a plurality of semiconductor substrates S due to variation of the flow rate (the introduction amount) of the etching gas, so that there is a risk that the thickness of the deposit PO varies. In this case, even when the slight ashing of a predetermined film thickness from the surface of the deposit PO is performed, the deposit PO may partially remain or may become a thin film and remain.

When impurity ions are implanted into such deposit PO and the hardened layer (HD) is formed, it can be considered that the internal pressure is partially increased inside the photoresist film. Therefore, the ashing temperature of the photoresist film PR5 described in the First Embodiment is set to a relatively low temperature, for example, a temperature lower than the ashing temperature of the photoresist films (for example, PR1 to PR4) that have been formed or the ashing temperature of the photoresist films (for example, PR6 to PR8) that will be formed. More specifically, the ashing temperature is set to around 110° C. to 120° C. Thereby, it is possible to further suppress the popping phenomenon of the photoresist film PR5.

### Application Example 2

In the etching of the element isolation region described in the First Embodiment, an adjustment of the flow rate of the etching gas may be performed with a high degree of accuracy. Specifically, the degree of accuracy of the flow rate of the etching gas, that is, the variation of the flow rate, may be adjusted within a range of ±1.5%.

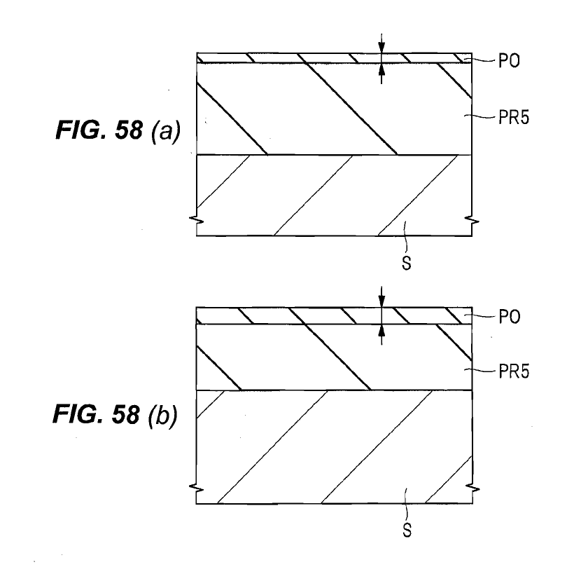

FIGS. 57 and 58 are cross-sectional views showing the manufacturing process of the semiconductor device of the comparative example. For example, when a regulator is used where the degree of accuracy of adjustment of the flow rate is not good and the scale of switching is 100 sccm (the flow rate can be adjusted in stages of 100 sccm), the variation of the flow rate may occur in a range of ±5%. When the etching gas is introduced at such a degree of accuracy, the amount of deposit (the film thickness) of the deposit PO may vary within the surface of the semiconductor substrate S (FIG. 57). Further, when a plurality of semiconductor substrates are sequentially processed, the amount of deposit (the film thickness) of the deposit PO may vary for each semiconductor substrate S (FIGS. 58A and 58B). In this case, even when the slight ashing of a predetermined film thickness from the surface of the deposit PO is performed, the deposit PO may partially remain or may become a thin film and remain.

On the other hand, as in the present embodiment, when the degree of accuracy of adjustment of the flow rate is improved, that is, for example, when a regulator is used where the scale of switching is 30 sccm (the flow rate can be adjusted in stages of 30 sccm), it is possible to suppress the variation of the flow rate within a range of ±1.5%. In this way, the etching is performed while adjusting the etching gas with a high degree of accuracy, so that the variation of the film thickness of the deposit PO is small. Therefore, it is possible to reduce the remaining amount of the deposit PO after the slight ashing of the deposit PO. Thus, it is possible to reduce the hardened layer (HD) formed when impurity ions are implanted into the remaining deposit PO, and it is possible to reduce the popping phenomenon due to the hardened layer HD.

The adjustment of the flow rate of the etching gas (the variation of the flow rate is ±1.5%) may be applied to the etching process of the element isolation region in the Second Embodiment.

### Fourth Embodiment

While in the First Embodiment, the slight ashing of the photoresist film is applied in the manufacturing process of the semiconductor device, which includes the ion implantation process after the etching process of the element isolation region, the slight ashing of the photoresist film can be widely applied. Specifically, the slight ashing of the photoresist film can be widely applied to a manufacturing process of a semiconductor device, which includes an ion implantation process using a photoresist film as a mask after an etching process using the photoresist film. Here, an example other than the application example described in the First Embodiment will be described.

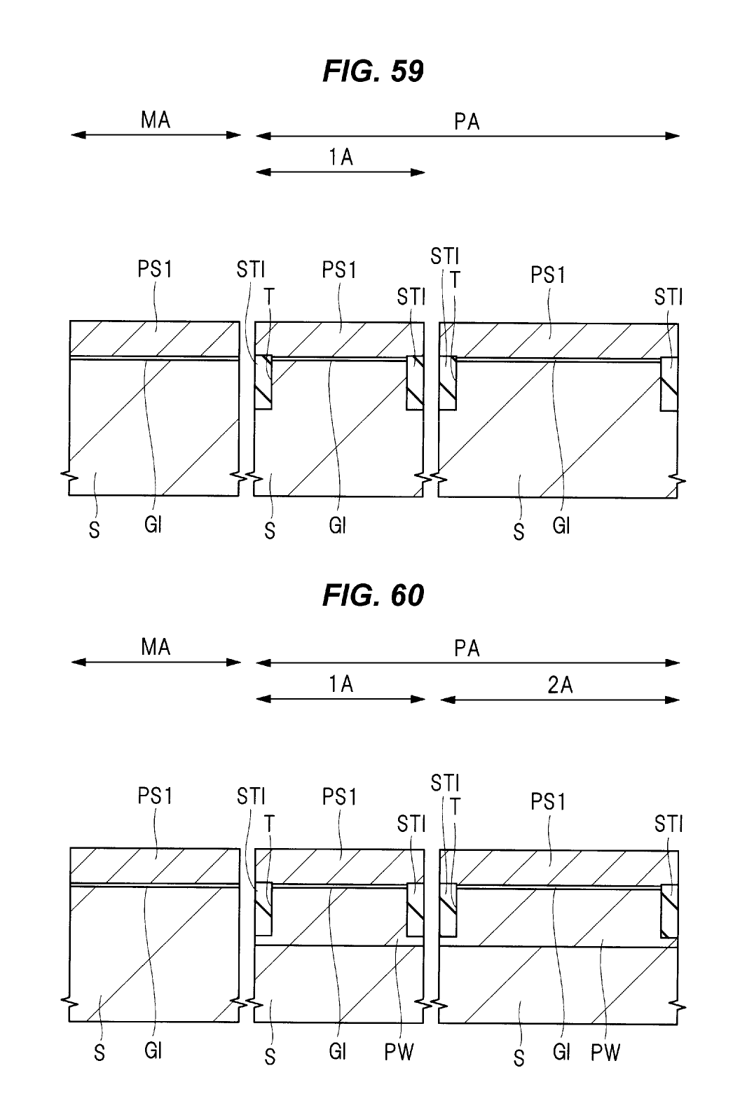

FIGS. 59 to 68 are cross-sectional views showing a manufacturing process of a semiconductor device of the present embodiment.

### [Description of Structure]

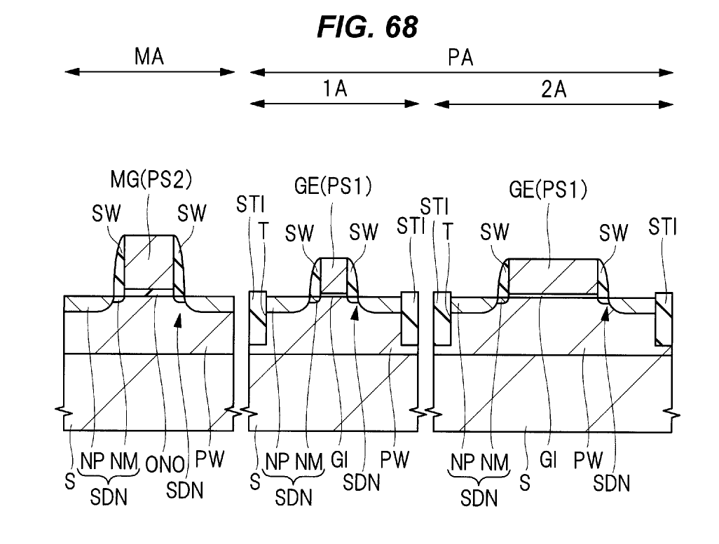

First, a configuration of the semiconductor device of the present embodiment will be described with reference to FIG. 68, which is a final process cross-sectional view, from among the drawings shown in FIGS. 59 to 68.

As shown in FIG. 68, the semiconductor device of the present embodiment includes a memory cell (memory transistor) formed in a memory cell region MA and a peripheral transistor formed in a peripheral circuit region PA. The semiconductor device of the present embodiment is, for example, an IC card with built-in flash memory.

The peripheral circuit region PA includes a core region 1A and an I/O region (input/output region) 2A. In the core region 1A, a low breakdown voltage transistor is formed. Here, as a low breakdown voltage transistor, an n-channel type transistor is illustrated. In the I/O region 2A, a high breakdown voltage transistor whose breakdown voltage is higher than that of the transistor formed in the core region 1A, and as the high breakdown voltage transistor, an n-channel type transistor is illustrated. The transistors formed in the peripheral circuit region PA are also called MISFET. Although only the n-channel type transistors are illustrated here as a high breakdown voltage transistor and a low breakdown voltage transistor, p-channel type transistors may be formed.

### (Description of Structure of Memory Cell)

The left figure in FIG. 68 is a cross-sectional view of the memory cell region MA. As shown in FIG. 68, the memory cell includes a memory gate MG arranged over the semiconductor substrate S (p-type well PW) through an insulating film ONO and a source/drain region SDN provided in the p-type wells PW on both sides of the memory gate MG. The memory gate MG is formed of a silicon film and a side wall insulating film SW formed of an insulating film is formed over a side wall portion of the memory gate MG. The source/drain region SDN includes an n⁺-type semiconductor region NP and an n⁻-type semiconductor region NM. The n⁻-type semiconductor region NM is formed in a self-aligned manner with respect to the side wall of the memory gate MG. The n⁺-type semiconductor region NP is formed in a self-aligned manner with respect to the side surface of the side wall insulating film SW. The junction depth of the n⁺-type semiconductor region NP is greater than that of the n⁻-type semiconductor region NM and the impurity concentration of the n⁺-type semiconductor region NP is higher than that of the n⁻-type semiconductor region NM. A metal silicide film may be formed over the memory gate MG and the source/drain region SDN (n⁺-type semiconductor region NP).

### (Description of Structure of Peripheral Transistor)

The low breakdown voltage transistor in the core region 1A (n-channel type transistor) and the high breakdown voltage transistor in the I/O region 2A (n-channel type transistor) have the same configurations as those in the First Embodiment, so that the detailed description thereof will be omitted.

### [Description of Manufacturing Method]

Next, a manufacturing method of the semiconductor device of the present embodiment will be described with reference to FIGS. 59 to 68.

Hereinafter, a process of forming a memory cell in the memory cell region MA and forming a peripheral transistor in the peripheral circuit region PA will be described with reference to the drawings.

First, as shown in FIG. 59, a semiconductor substrate formed of a silicon single crystal is prepared as the semiconductor substrate S. Subsequently, an element isolation region STI is formed. First, a trench T is formed in the semiconductor substrate S, and a silicon oxide film having a thickness to fill the inside of the trench T is deposited by using the CVD method or the like. Subsequently, the silicon oxide film other than the silicon oxide film in the trench T is removed by using the CMP method or the like. Thereby, it is possible to form the element isolation region STI formed of an insulating film buried inside the trench T. Each region is separated from each other by the element isolation region STI.

Subsequently, a gate insulating film GI is formed over the surface of the semiconductor substrate S. For example, a silicon oxide film is formed over each region of the semiconductor substrate S by the thermal oxidation method. The thickness of the silicon oxide film may be changed for each region. The type of the silicon oxide film to be used may be changed for each region.

Subsequently, a polycrystalline silicon film PS1 is deposited over the gate insulating film GI and the element isolation region STI by using the CVD method or the like. The silicon film PS1 becomes the gate electrode GE in the peripheral circuit region PA.

Subsequently, as shown in FIG. 60, a p-type well PW is formed in the peripheral circuit region PA of the semiconductor substrate S. For example, the p-type well PW is formed by ion-implanting p-type impurities into the peripheral circuit region PA through the silicon film PS1. Regions into which ions are not implanted are covered by a photoresist film (not shown in the drawings).

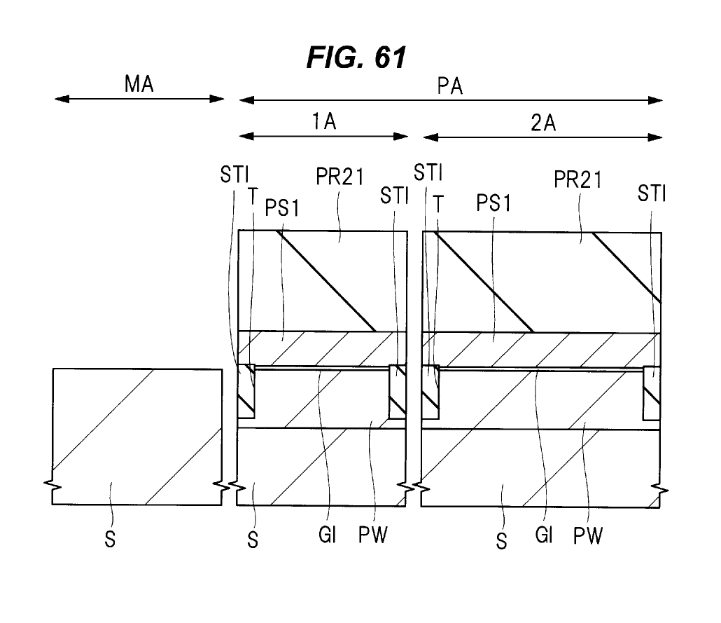

Subsequently, as shown in FIG. 61, a photoresist film PR21 that covers the silicon film PS1 in the peripheral circuit region PA is formed. Subsequently, the silicon film PS1 in the memory cell region MA is removed by etching by using the photoresist film PR21 as a mask.

Specifically, the silicon film PS1 is dry-etched by using the photoresist film PR21 as a mask. In the dry etching, as described in detail in the First Embodiment, the etching with depositional characteristics is performed. According to such etching, it is possible to reduce the thickness reduction of the photoresist film and improve the accuracy of the etching. As a gas used for the etching, for example, fluorocarbon gas such as CF₄, CHF₃, CH₂F₂, C₄F₈, C₄F₆, and C₅F₈ can be used. When the gas as described above is used, while a film to be etched is being etched by CF radicals (CF*, CF₂*, and CF₃*), deposit including fluorocarbon-based polymer (CF-based polymer) is deposited over the upper surface and the side surface of the photoresist film as an etching by-product, so that the photoresist film can be protected. The semiconductor substrate S in the memory cell region MA is exposed by the above etching (see FIG. 61).

Subsequently, the surface of the photoresist film PR21 is etched (slightly asked). For example, the etching is performed by using oxygen or ozone as an etching gas. Ar may be introduced into an etching atmosphere. It is not necessarily essential to add Ar into the etching gas and apply a substrate bias. However, when elements whose mass number is greater than that of oxygen are added into the etching gas and the substrate bias is applied, a sputtering effect is improved and an etching speed is improved. When the slight ashing is performed on the photoresist film PR21 in this way, it is possible to remove the deposit that is deposited over the surface of the photoresist film PR21 during the dry etching of the element isolation region STI (see FIG. 1).

It is preferable that the slight ashing is performed by the same etching apparatus used for the dry etching of the silicon film PS1. It is possible to perform a series of processes in a short time by using the same apparatus as described above. Further, when the same apparatus is used, it is possible to prevent the deposit PO from coming into contact with the atmosphere and changing in quality, so that it is possible to effectively remove the deposit PO.

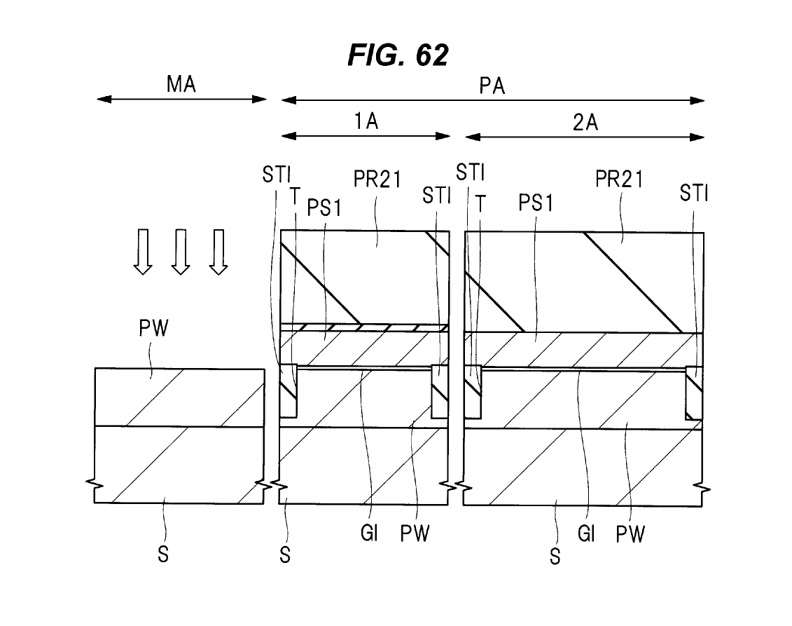

Subsequently, a p-type well PW is formed by ion-implanting p-type impurities into the semiconductor substrate S of the memory cell region MA by using the photoresist film PR21 as a mask (see FIG. 62).

Subsequently, the photoresist film PR21 is removed by ashing. As an ashing condition, in this ashing, as described above, carbon (C) and hydrogen (H), which are main components of the photoresist film, react with oxygen (O₂) to form CO₂, CO, and H₂O (water vapor) and they are vaporized. This ashing condition is the same as the ashing condition of the photoresist films described above. Here, even when a bias potential is not applied to the substrate, the ashing process progresses quickly. However, as an ashing condition, Ar may be added to the gas and the bias potential may be applied to the substrate.

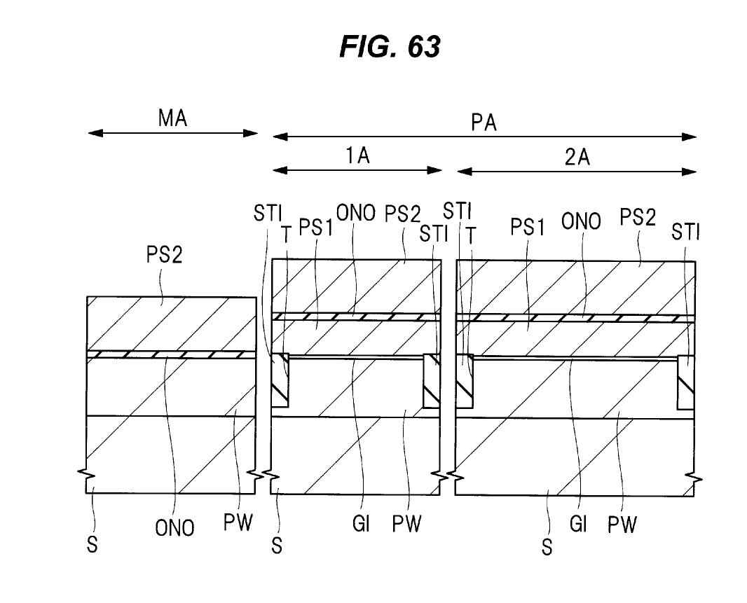

Subsequently, as shown in FIG. 63, a polycrystalline silicon film PS2 is formed in the memory cell region MA and the peripheral circuit region PA through the insulating film ONO. For example, a silicon oxide film is formed over the p-type well PW in the memory cell region MA and the silicon film PS1 in the peripheral circuit region PA by the thermal oxidation method. Subsequently, a silicon nitride film is deposited over the silicon oxide film by the CVD method or the like. The silicon nitride film becomes a charge accumulation unit of the memory cell and becomes an intermediate layer that forms the insulating film ONO. Subsequently, a silicon oxide film is deposited over the silicon nitride film by the CVD method. Thereby, the insulating film ONO including the silicon oxide film, the silicon nitride film, and the silicon oxide film can be formed.

Subsequently, the polycrystalline silicon film PS2 is deposited over the insulating film ONO by using the CVD method or the like. The silicon film PS2 becomes a memory gate MG in the memory cell region MA.

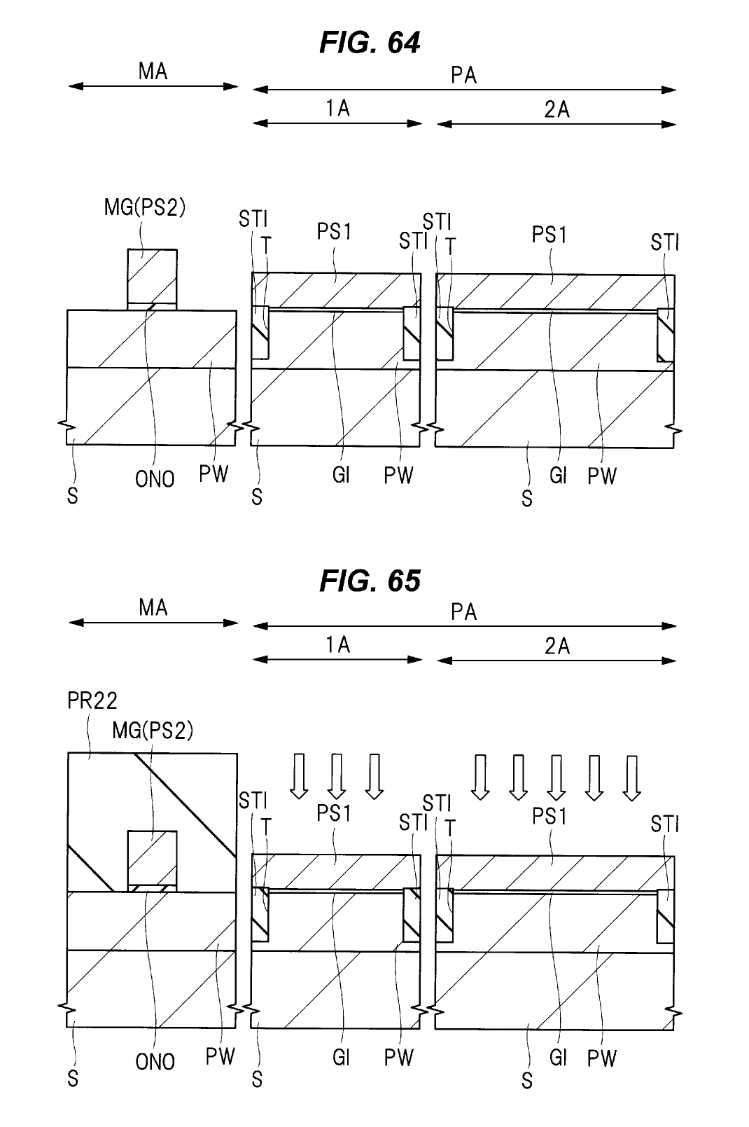

Subsequently, as shown in FIG. 64, the memory gate MG is formed. For example, a photoresist film (not shown in FIG. 64) is caused to remain in a region where the memory gate MG will be formed, and the silicon film PS2 is dry-etched by using the photoresist film as a mask, so that the memory gate MG is formed in the memory cell region MA. In this process, the insulating film ONO and the silicon film PS2 in the peripheral circuit region PA are removed and the silicon film PS1 is exposed.

Subsequently, as shown in FIG. 65, impurity ions are implanted into the silicon film PS1 in the peripheral circuit region PA. For example, a photoresist film PR22 that covers the memory cell region MA is formed, and impurity ions are implanted into the silicon film PS1 in the peripheral circuit region PA by using the photoresist film as a mask. Subsequently, the photoresist film PR22 is removed by ashing.

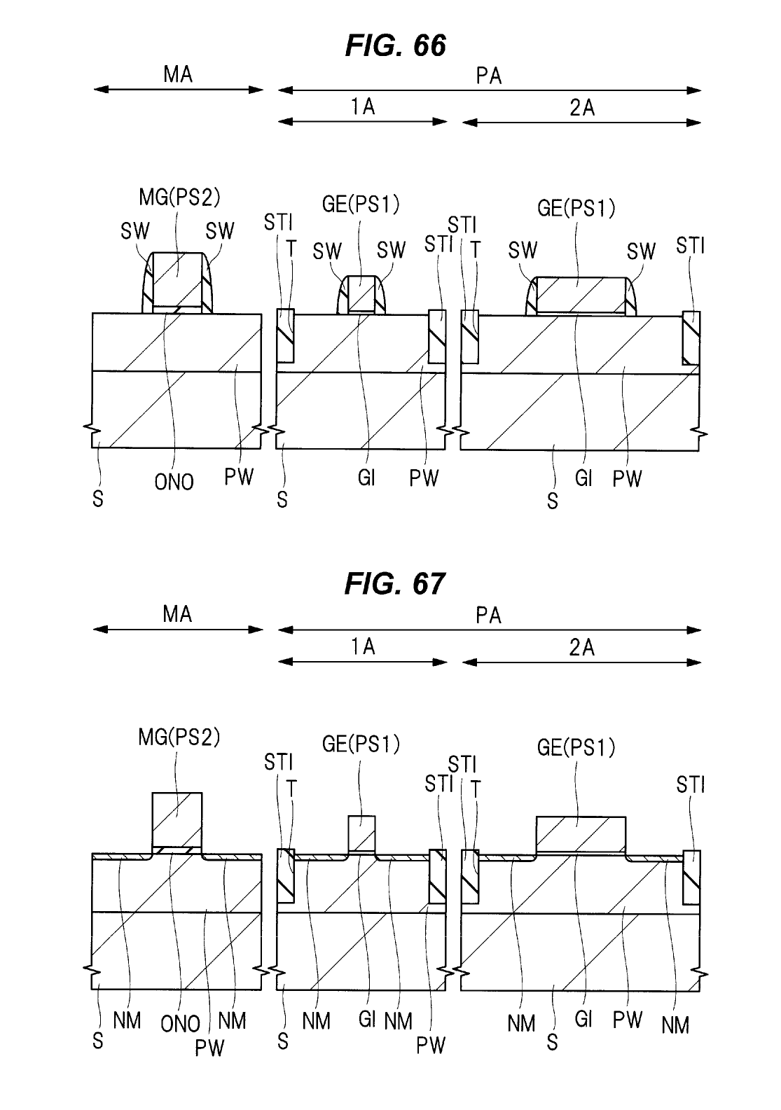

Subsequently, as shown in FIG. 66, the gate electrode GE in the peripheral circuit region PA is formed. For example, a photoresist film (not shown in FIG. 66) is caused to remain in a region where the gate electrode GE will be formed, and the silicon film PS1 is dry-etched by using the photoresist film as a mask.

Subsequently, as shown in FIG. 67, an n⁻-type semiconductor region NM is formed in p-type wells PW on both sides of the memory gate MG and the gate electrode GE. For example, the n⁻-type semiconductor region NM is formed by ion-implanting n-type impurities into the p-type wells PW on both sides of the memory gate MG and the gate electrode GE. Regions where the ion implantation is not required (for example, a region where a p-channel type transistor is formed) are covered by a photoresist film. Subsequently, the photoresist film is removed by ashing.

Subsequently, as shown in FIG. 68, an n⁺-type semiconductor region NP is formed in p-type wells PW on both sides of the memory gate MG and the gate electrode GE. First, a side wall insulating film SW is formed over the side wall portions of the memory gate MG and the gate electrode GE. For example, a silicon oxide film is deposited over the semiconductor substrate S by using the CVD method or the like. The silicon oxide film is removed by a predetermined thickness from the surface thereof by anisotropic dry etching, so that the side wall insulating film SW is formed over the side wall portions of the memory gate MG and the gate electrode GE. Subsequently, an n⁺-type semiconductor region NP is formed by implanting n-type impurities (for example, phosphorus (P)) by using the memory gate MG, the gate electrode GE, and the side wall insulating film SW as a mask. In this case, the n⁺-type semiconductor region NP is formed by being self-aligned to the side wall insulating film SW. The impurity concentration of the n⁺-type semiconductor region NP is higher than that of the n⁻-type semiconductor region NM and the junction depth of the n⁺-type semiconductor region NP is greater than that of the n⁻-type semiconductor region NM. By this process, the source/drain region SDN including then⁻-type semiconductor region NM and the n⁺-type semiconductor region NP is formed. Regions where the ion implantation is not required (for example, a region where a p-channel type transistor is formed) are covered by a photoresist film. Subsequently, the photoresist film is removed by ashing.

Thereafter, in the same manner as in the First Embodiment, a metal silicide film SIL is formed over the memory gate MG, the gate electrode GE, and the source/drain region SDN by using a salicide technique. Further, an interlayer insulating film IL1 is formed over the memory gate MG and the gate electrode GE, and then a plug P1 is formed in the interlayer insulating film IL1, and further a wiring M1 is formed over the interlayer insulating film IL1 and the plug P1. Two or more layers of wiring may be formed by repeating the forming process of the interlayer insulating film, the plug, and the wiring.

It is possible to form the semiconductor device of the present embodiment by the process described above. As described above, according to the present embodiment, it is possible to suppress the popping phenomenon of the photoresist film and form a semiconductor device having excellent characteristics. Further, it is possible to improve the yield rate of the semiconductor device. That is, when the silicon film PS1 is etched by using the photoresist film PR21 as a mask (FIG. 61), the deposit (PO) formed over the surface of the photoresist film PR21 is removed by slight ashing, and thereafter the p-type well PW is formed in the memory cell region MA by performing ion implantation (FIG. 62), so that it is possible to suppress the popping phenomenon of the photoresist film PR21 during ashing.

In the manufacturing process of the semiconductor device of the present embodiment, it is also possible to apply the low temperature ashing of the photoresist film PR5 described in the application example 1 of the Third Embodiment. When the silicon film PS1 is etched, the variation of the flow rate described in the application example 2 of the Third Embodiment may be adjusted in a range of ±1.5%.

Also in the manufacturing process of the semiconductor device of the present embodiment, it is possible to apply the low temperature ashing and the omission of the slight ashing of the photoresist film PR5 described in the Second Embodiment.

While the invention made by the inventors has been specifically described based on the embodiments, the invention is not limited to the embodiments, but needless to say that the invention may be modified in various ways without departing from the scope of the invention.

### APPENDIX 1

A manufacturing method of a semiconductor device, which includes the steps of
(a) forming a first photoresist film above a semiconductor substrate,
(b) removing the first photoresist film at a first temperature,
(c) forming a second photoresist film above an insulating film formed over the semiconductor substrate,
(d) exposing and developing the second photoresist film,
(e) after the step (d), exposing the semiconductor substrate under the insulating film by etching the insulating film by using the second photoresist film as a mask,
(f) after the step (e), implanting impurity ions into the semiconductor substrate under the insulating film by using the second photoresist film as a mask, and
(g) after the step (f), removing the second photoresist film at a second temperature lower than the first temperature.

### APPENDIX 2

The manufacturing method of a semiconductor device according to appendix 1,

in which the step (e) is a step of etching the insulating film while forming deposit over the second photoresist film.

### APPENDIX 3

The manufacturing method of a semiconductor device according to appendix 2,

in which the second temperature is 110° C. or more and 120° C. or less.

### APPENDIX 4

A manufacturing method of a semiconductor device, which includes the steps of
(a) forming a first photoresist film above a semiconductor substrate,
(b) removing the first photoresist film at a first temperature,
(c) forming a second photoresist film over a conductive film formed over the semiconductor substrate,
(d) exposing and developing the second photoresist film,
(e) after the step (d), etching the conductive film by using the second photoresist film as a mask,
(f) after the step (e), implanting impurity ions into the semiconductor substrate by using the second photoresist film as a mask, and
(g) after the step (f), removing the second photoresist film at a second temperature lower than the first temperature.

### APPENDIX 5

The manufacturing method of a semiconductor device according to appendix 4,

in which the step (e) is a step of etching the conductive film while forming deposit over the second photoresist film.

### APPENDIX 6

The manufacturing method of a semiconductor device according to appendix 5,

in which the second temperature is 110° C. or more and 120° C. or less.

What is claimed is:

1. A manufacturing method of a semiconductor device, comprising the steps of:
(a) forming a photoresist film above an insulating film formed over a semiconductor substrate;
(b) exposing and developing the photoresist film;
(c) after the step (b), exposing the semiconductor substrate under the insulating film by etching the insulating film by using the photoresist film as a mask;
(d) after the step (c), etching a surface of the photoresist film;
(e) after the step (d), implanting impurity ions into the semiconductor substrate by using the photoresist film as a mask; and
(f) after the step (e), removing the photoresist film.

2. The manufacturing method of a semiconductor device according to claim 1,
wherein the step (c) is a step of etching the insulating film while forming deposit over the photoresist film, and
the step (d) is a step of etching the deposit over the photoresist film.

3. The manufacturing method of a semiconductor device according to claim 2,
wherein the step (c) is a step in which fluorocarbon gas is used as an etching gas.

4. The manufacturing method of a semiconductor device according to claim 2,
wherein the step (d) is a step in which oxygen or ozone is used as an etching gas.

5. The manufacturing method of a semiconductor device according to claim 4,
wherein the etching gas contains elements whose mass number is greater than that of an oxygen atom.

6. The manufacturing method of a semiconductor device according to claim 5,
wherein the element is argon (Ar).

7. The manufacturing method of a semiconductor device according to claim 6,
wherein an amount of etching in the step (d) is in a range greater than or equal to 50 nm and smaller than or equal to 300 nm.

8. The manufacturing method of a semiconductor device according to claim 3,
wherein a variation of a flow rate of the etching gas in the step (c) is adjusted in a range of ±1.5%.

9. The manufacturing method of a semiconductor device according to claim 1,
wherein the step (f) is performed at 110° C. or more and 120° C. or less.

10. The manufacturing method of a semiconductor device according to claim 1,
wherein the step (c) is a step of etching the insulating film located between gate electrodes, and
the photoresist film has an opening portion over a gap between the gate electrodes.

11. A manufacturing method of a semiconductor device, comprising the steps of:
(a) forming a photoresist film above a conductive film formed over a semiconductor substrate;
(b) exposing and developing the photoresist film;
(c) after the step (b), etching the conductive film by using the photoresist film as a mask;
(d) after the step (c), etching a surface of the photoresist film;
(e) after the step (d), implanting impurity ions into the semiconductor substrate by using the photoresist film as a mask; and
(f) after the step (e), removing the photoresist film.

12. The manufacturing method of a semiconductor device according to claim 11,
wherein the step (c) is a step of etching the conductive film while forming deposit over the photoresist film, and
the step (d) is a step of etching the deposit over the photoresist film.

13. The manufacturing method of a semiconductor device according to claim 12,
wherein the step (c) is a step in which fluorocarbon gas is used as an etching gas.

14. The manufacturing method of a semiconductor device according to claim 12,
wherein the step (d) is a step in which oxygen or ozone is used as an etching gas.

15. The manufacturing method of a semiconductor device according to claim 14,
wherein the etching gas contains elements whose mass number is greater than that of an oxygen atom.

16. The manufacturing method of a semiconductor device according to claim 15,
wherein the element is argon (Ar).

17. The manufacturing method of a semiconductor device according to claim 16,
wherein an amount of etching in the step (d) is in a range greater than or equal to 50 nm and smaller than or equal to 300 nm.

18. The manufacturing method of a semiconductor device according to claim 13,
wherein a variation of a flow rate of the etching gas in the step (c) is adjusted in a range of ±1.5%.

19. The manufacturing method of a semiconductor device according to claim 11,
wherein the step (f) is performed at 110° C. or more and 120° C. or less.

20. A manufacturing method of a semiconductor device, comprising the steps of:
(a) forming a first photoresist film above a semiconductor substrate;
(b) removing the first photoresist film at a first temperature;
(c) forming a second photoresist film above an insulating film formed over the semiconductor substrate;
(d) exposing and developing the second photoresist film;
(e) after the step (d), exposing the semiconductor substrate under the insulating film by etching the insulating film by using the second photoresist film as a mask;
(f) after the step (e), implanting impurity ions into the semiconductor substrate under the insulating film by using the second photoresist film as a mask; and
(g) after the step (f), removing the second photoresist film at a second temperature lower than the first temperature.
